(19) United States
(12) Patent Application Publication
(10) Pub. No.: US 2019/0385969 A1
(43) Pub. Date: Dec. 19, 2019

(54) COAXIAL WIRE

(71) Applicant: The Charles Stark Draper Laboratory, Inc., Cambridge, MA (US)

(72) Inventors: Caprice Gray Haley, Cambridge, MA (US); Robert McCormick, Cambridge, MA (US); Anthony Kopa, Cambridge, MA (US); John Lachapelle, Cambridge, MA (US); Amy Duwel, Cambridge, MA (US); Sara Barron, Cambridge, MA (US); Andrew P. Magyar, Cambridge, MA (US)

(21) Appl. No.: 16/442,259

(22) Filed: Jun. 14, 2019

Related U.S. Application Data
(60) Provisional application No. 62/684,793, filed on Jun. 14, 2018.
(60) Provisional application No. 62/694,075, filed on Jul. 5, 2018.

(51) Int. Cl. H01L 23/00; H01L 23/538; H01L 23/49; H01L 23/498; H01L 23/31; H01L 21/48

(52) U.S. Cl. CPC H01L 24/45; H01L 2224/43125; H01L 23/49; H01L 23/49811; H01L 23/3107; H01L 24/48; H01L 24/49; H01L 24/73; H01L 24/16; H01L 24/745; H01L 24/43; H01L 21/4896; H01L 2224/45005; H01L 2224/45015; H01L 2224/45139; H01L 2224/45147; H01L 2224/45541; H01L 2224/45572; H01L 2224/4569; H01L 2224/45644; H01L 2224/45647; H01L 2224/48137; H01L 2224/48225; H01L 2224/4903; H01L 2224/49112; H01L 2224/4917; H01L 2224/73207; H01L 2224/16235; H01L 2224/16227; H01L 2224/432; H01L 23/5386

(57) ABSTRACT

A micro-coaxial wire has an overall diameter in a range of 0.1 μm-550 μm, a conductive core of the wire has a cross-sectional diameter in a range of 0.05 μm-304 μm, an insulator is disposed on the conductive core with thickness in a range of 0.005 μm-180 μm, and a conductive shield layer is disposed on the insulator with thickness in a range of 0.009 μm-99 μm.

### CROSS-REFERENCE TO RELATED APPLICATIONS

This application claims the benefit of U.S. Provisional Application No. 62/684,793 filed Jun. 14, 2018 and U.S. Provisional Application No. 62/694,075 filed Jul. 5, 2018, both of which are incorporated herein by reference.

### BACKGROUND

This invention relates to wiring systems.

With today's high density interconnection technology, skilled engineers require weeks or months to design and layout a multi-layer printed circuit board. For high-volume manufacturing this non-recurring engineering (NRE) cost is amortized over thousands or more units. For prototypes and low-volume manufacturing, this NRE is a major cost contributor that cannot be amortized.

### SUMMARY

In a general aspect, an outer diameter of a micro-coaxial wire with a 50-Ohm impedance is in a range of 0.2 μm-550 μm, a diameter of the core of the wire is in a range of 0.1 μm-130 μm, a thickness of a dielectric layer of the wire is in a range of 0.09 μm-180 μm, and a thickness of a shield layer of the wire is in a range of 009 μm-17 μm.

Aspects may have one or more of the following features.

An outer diameter of a micro-coaxial wire with a 50-Ohm impedance may be in a range of 412 μm-550 μm, a diameter of the core of the wire may be in a range of 103 μm-130 μm, a thickness of a dielectric layer of the wire may be in a range of 141 μm-180 μm, and a thickness of a shield layer of the wire may be in a range of 13 μm-17 μm. An outer diameter of a micro-coaxial wire with a 50-Ohm impedance may be approximately 506 μm, a diameter of the core of the wire may be approximately 127 μm, a thickness of a dielectric layer of the wire may be approximately 174 μm, and a thickness of a shield layer of the wire may be approximately 15.9 μm.

An outer diameter of a micro-coaxial wire with a 50-Ohm impedance may be in a range of 260 μm-412 μm, a diameter of the core of the wire may be in a range of 65 μm-103 μm, a thickness of a dielectric layer of the wire may be in a range of 89 μm-141 μm, and a thickness of a shield layer of the wire may be in a range of 8.2 μm-13 μm. An outer diameter of a micro-coaxial wire with a 50-Ohm impedance may be approximately 318 μm, a diameter of the core of the wire may be approximately 79.9 μm, a thickness of a dielectric layer of the wire may be approximately 109 μm, and a thickness of a shield layer of the wire may be approximately 10 μm.

An outer diameter of a micro-coaxial wire with a 50-Ohm impedance may be in a range of 150 μm-260 μm, a diameter of the core of the wire may be in a range of 38 μm-65 μm, a thickness of a dielectric layer of the wire may be in a range of Slum-89 μm, and a thickness of a shield layer of the wire may be in a range of 4.7 μm 8.2 μm. An outer diameter of a micro-coaxial wire with a 50-Ohm impedance may be approximately 200 μm, a diameter of the core of the wire may be approximately 50.2 μm, a thickness of a dielectric layer of the wire may be approximately 68.7 μm, and a thickness of a shield layer of the wire may be approximately 6.31 μm.

An outer diameter of a micro-coaxial wire with a 50-Ohm impedance may be in a range of 90 μm-150 μm, a diameter of the core of the wire may be in a range of 23 μm-38 μm, a thickness of a dielectric layer of the wire may be in a range of 31 μm-51 μm, and a thickness of a shield layer of the wire may be in a range of 2.8 μm 4.7 μm. An outer diameter of a micro-coaxial wire with a 50-Ohm impedance may be approximately 99.9 μm, a diameter of the core of the wire may be approximately 25.1 μm, a thickness of a dielectric layer of the wire may be approximately 34.3 μm, and a thickness of a shield layer of the wire may be approximately 3.14 μm.

An outer diameter of a micro-coaxial wire with a 50-Ohm impedance may be in a range of 60 μm-90 μm, a diameter of the core of the wire may be in a range of 14.9 μm 23 μm, a thickness of a dielectric layer of the wire may be in a range of 20 μm-31 μm, and a thickness of a shield layer of the wire may be in a range of 1.9 μm 2.8 μm. An outer diameter of a micro-coaxial wire with a 50-Ohm impedance may be approximately 79.2 μm, a diameter of the core of the wire may be approximately 19.9 μm, a thickness of a dielectric layer of the wire may be approximately 27.2 μm, and a thickness of a shield layer of the wire may be approximately 2.49 μm.

An outer diameter of a micro-coaxial wire with a 50-Ohm impedance may be in a range of 30 μm-60 μm, a diameter of the core of the wire may be in a range of 7.4 μm 14.9 μm, a thickness of a dielectric layer of the wire may be in a range of 10 μm-20 μm, and a thickness of a shield layer of the wire may be in a range of 0.9 μm 1.9 μm. An outer diameter of a micro-coaxial wire with a 50-Ohm impedance may be approximately 39.5 μm, a diameter of the core of the wire may be approximately 9.9 μm, a thickness of a dielectric layer of the wire may be approximately 13.5 μm, and a thickness of a shield layer of the wire may be approximately 1.24 μm.

An outer diameter of a micro-coaxial wire with a 50-Ohm impedance may be in a range of 12 μm-30 μm, a diameter of the core of the wire may be in a range of 3 μm 7.4 μm, a thickness of a dielectric layer of the wire may be in a range of 4 μm-10 μm, and a thickness of a shield layer of the wire may be in a range of 0.4 μm-0.9 μm. An outer diameter of a micro-coaxial wire with a 50-Ohm impedance may be approximately 19.7 μm, a diameter of the core of the wire may be approximately 4.9 μm, a thickness of a dielectric layer of the wire may be approximately 6.76 μm, and a thickness of a shield layer of the wire may be approximately 0.62 μm.

An outer diameter of a micro-coaxial wire with a 50-Ohm impedance may be in a range of 2 μm-12 μm, a diameter of the core of the wire may be in a range of 0.6 μm 3 μm, a thickness of a dielectric layer of the wire may be in a range of 0.7 μm-4 μm, and a thickness of a shield layer of the wire may be in a range of 0.06 μm-0.4 μm. An outer diameter of a micro-coaxial wire with a 50-Ohm impedance may be approximately 3.98 μm, a diameter of the core of the wire may be approximately a thickness of a dielectric layer of the wire may be approximately 1.38 μm, and a thickness of a shield layer of the wire may be approximately 0.12 μm.

An outer diameter of a micro-coaxial wire with a 50-Ohm impedance may be in a range of 0.2 μm 2 μm, a diameter of the core of the wire may be in a range of 0.05 μm 0.6 μm, a thickness of a dielectric layer of the wire may be in a range of 0.05 μm-0.7 μm, and a thickness of a shield layer of the wire may be in a range of 0.005 μm 0.06 μm. An outer diameter of a micro-coaxial wire with a 50-Ohm impedance may be approximately 0.3 μm, a diameter of the core of the wire may be approximately 0.1 μm, a thickness of a dielectric layer of the wire may be approximately 0.1 μm, and a thickness of a shield layer of the wire may be approximately 0.01 μm.

In another general aspect, an outer diameter of a micro-coaxial wire with a 5-Ohm impedance may be in a range of 0.1 μm-550 μm, a diameter of the core of the wire may be in a range of 0.05 μm-304 μm, a thickness of a dielectric layer of the wire may be in a range of 0.005 μm-24 μm, and a thickness of a shield layer of the wire may be in a range of 0.02 μm-99 μm.

Aspects may have one or more of the following features.

An outer diameter of a micro-coaxial wire with a 5-Ohm impedance may be in a range of 365 μm-550 μm, a diameter of the core of the wire may be in a range of 202 μm-304 μm, a thickness of a dielectric layer of the wire may be in a range of 16 μm-24 μm, and a thickness of a shield layer of the wire may be in a range of 66 μm-99 μm. An outer diameter of a micro-coaxial wire with a 5-Ohm impedance may be approximately 500 μm, a diameter of the core of the wire may be approximately 276 μm, a thickness of a dielectric layer of the wire may be approximately 21.4 μm and a thickness of a shield layer of the wire may be approximately 90.3 μm.

An outer diameter of a micro-coaxial wire with a 5-Ohm impedance may be in a range of 166 μm-365 μm, a diameter of the core of the wire may be in a range of 92 μm-202 μm, a thickness of a dielectric layer of the wire may be in a range of 7.1 μm-16 μm, and a thickness of a shield layer of the wire may be in a range of 30 μm-66 μm. An outer diameter of a micro-coaxial wire with a 5-Ohm impedance may be approximately 230 μm, a diameter of the core of the wire may be approximately 127 μm, a thickness of a dielectric layer of the wire may be approximately 9.86 μm and a thickness of a shield layer of the wire may be approximately 41.5 μm.

An outer diameter of a micro-coaxial wire with a 5-Ohm impedance may be in a range of 87 μm-166 μm, a diameter of the core of the wire may be in a range of 48 μm-92 μm, a thickness of a dielectric layer of the wire may be in a range of 3.7 μm-7.1 μm, and a thickness of a shield layer of the wire may be in a range of 15.7 μm-30 μm. An outer diameter of a micro-coaxial wire with a 5-Ohm impedance may be approximately 102 μm, a diameter of the core of the wire may be approximately 56.4 μm, a thickness of a dielectric layer of the wire may be approximately 4.38 μm and a thickness of a shield layer of the wire may be approximately 18.4 μm.

An outer diameter of a micro-coaxial wire with a 5-Ohm impedance may be in a range of 61 μm-87 μm, a diameter of the core of the wire may be in a range of 34 μm-48 μm, a thickness of a dielectric layer of the wire may be in a range of 2.6 μm-3.7 μm, and a thickness of a shield layer of the wire may be in a range of 11.1 μm-15.7 μm. An outer diameter of a micro-coaxial wire with a 5-Ohm impedance may be approximately 72.1 μm, a diameter of the core of the wire may be approximately 39.8 μm, a thickness of a dielectric layer of the wire may be approximately 3.09 μm and a thickness of a shield layer of the wire may be approximately 13 μm.

An outer diameter of a micro-coaxial wire with a 5-Ohm impedance may be in a range of 48 μm-61 μm, a diameter of the core of the wire may be in a range of 26.6 μm-34 μm, a thickness of a dielectric layer of the wire may be in a range of 2.1 μm-2.6 μm, and a thickness of a shield layer of the wire may be in a range of 8.7 μm-11.1 μm. An outer diameter of a micro-coaxial wire with a 5-Ohm impedance may be approximately 50.9 μm, a diameter of the core of the wire may be approximately 28.1 μm, a thickness of a dielectric layer of the wire may be approximately 2.18 μm and a thickness of a shield layer of the wire may be approximately 9.2 μm.

An outer diameter of a micro-coaxial wire with a 5-Ohm impedance may be in a range of 35 μm-48 μm, a diameter of the core of the wire may be in a range of 19.6 μm-26.6 μm, a thickness of a dielectric layer of the wire may be in a range of 1.5 μm-2.1 μm, and a thickness of a shield layer of the wire may be in a range of 6.4 μm-8.7 μm. An outer diameter of a micro-coaxial wire with a 5-Ohm impedance may be approximately 45.3 μm, a diameter of the core of the wire may be approximately 25.1 μm, a thickness of a dielectric layer of the wire may be approximately 1.95 μm and a thickness of a shield layer of the wire may be approximately 8.19 μm.

An outer diameter of a micro-coaxial wire with a 5-Ohm impedance may be in a range of 22.8 μm-35 μm, a diameter of the core of the wire may be in a range of 12.6 μm-19.6 μm, a thickness of a dielectric layer of the wire may be in a range of 1μm-1.5 μm, and a thickness of a shield layer of the wire may be in a range of 4.1 μm-6.4 μm. An outer diameter of a micro-coaxial wire with a 5-Ohm impedance may be approximately 25.4 μm, a diameter of the core of the wire may be approximately 14 μm, a thickness of a dielectric layer of the wire may be approximately 1.09 μm and a thickness of a shield layer of the wire may be approximately 4.59 μm.

An outer diameter of a micro-coaxial wire with a 5-Ohm impedance may be in a range of 15 μm-22.8 μm, a diameter of the core of the wire may be in a range of 8.3 μm-12.6 μm, a thickness of a dielectric layer of the wire may be in a range of 0.6 μm-1 μm, and a thickness of a shield layer of the wire may be in a range of 2.7 μm-4.1 μm. An outer diameter of a micro-coaxial wire with a 5-Ohm impedance may be approximately 20.1 μm, a diameter of the core of the wire may be approximately 11.1 μm, a thickness of a dielectric layer of the wire may be approximately 0.86 μm and a thickness of a shield layer of the wire may be approximately 3.64 μm.

An outer diameter of a micro-coaxial wire with a 5-Ohm impedance may be in a range of 6 μm-15 μm, a diameter of the core of the wire may be in a range of 3.3 μm-8.3 μm, a thickness of a dielectric layer of the wire may be in a range of 0.25 μm-0.6 μm, and a thickness of a shield layer of the wire may be in a range of 1.1 μm-2.7 μm. An outer diameter of a micro-coaxial wire with a 5-Ohm impedance may be approximately 10 μm, a diameter of the core of the wire may be approximately 5.5 μm, a thickness of a dielectric layer of the wire may be approximately 0.43 μm and a thickness of a shield layer of the wire may be approximately 1.81 μm.

An outer diameter of a micro-coaxial wire with a 5-Ohm impedance may be in a range of 0.16 μm-6 μm, a diameter of the core of the wire may be in a range of 0.55 μm-3.3 μm, a thickness of a dielectric layer of the wire may be in a range of 0.04 μm-0.25 μm, and a thickness of a shield layer of the wire may be in a range of 0.17 μm-1.1 μm. An outer diameter of a micro-coaxial wire with a 5-Ohm impedance may be approximately 1.76 μm, a diameter of the core of the wire may be approximately a thickness of a dielectric layer of the wire may be approximately 0.08 μm and a thickness of a shield layer of the wire may be approximately 0.32 μm.

An outer diameter of a micro-coaxial wire with a 5-Ohm impedance may be in a range of 0.1 μm-0.16 μm, a diameter of the core of the wire may be in a range of 0.05 μm-0.55 μm, a thickness of a dielectric layer of the wire may be in a range of 0.005 μm-0.04 μm, and a thickness of a shield layer of the wire may be in a range of 0.02 μm-0.17 μm. An outer diameter of a micro-coaxial wire with a 5-Ohm impedance may be approximately 0.14 μm, a diameter of the core of the wire may be approximately 0.1 μm, a thickness of a dielectric layer of the wire may be approximately 0.01 μm and a thickness of a shield layer of the wire may be approximately 0.03 μm.

In a general aspect, a coaxial wire has a conductive core with a cross-sectional diameter in a range of 7 μm-50 μm, an insulator disposed on the conductive core with thickness in a range of 1 μm-30 μm, and a conductive shield layer disposed on the insulator with thickness in a range of 2 μm-10 μm.

Aspects may have one or more of the following features.

The cross-sectional diameter of the conductive core may be 25 μm, the thickness of the insulator may be 1.3 μm, and the thickness of the shield thickness may be 9 μm. The cross-sectional diameter of the conductive core may be 25 μm, the thickness of the insulator may be 1.3 μm, and the thickness of the shield thickness may be 5μm.

The cross-sectional diameter of the conductive core may be 25 μm, the thickness of the insulator may be and the thickness of the shield thickness may be 8 μm.

The cross-sectional diameter of the conductive core may be 17 μm, the thickness of the insulator may be 1.3 μm, and the thickness of the shield thickness may be 6 μm. The cross-sectional diameter of the conductive core may be 17 μm, the thickness of the insulator may be 1.3 μm, and the thickness of the shield thickness may be 4 μm.

The cross-sectional diameter of the conductive core may be 10 μm, the thickness of the insulator may be and the thickness of the shield thickness may be 2.5 μm. The cross-sectional diameter of the conductive core may be 10 μm, the thickness of the insulator may be and the thickness of the shield thickness may be 3.5 μm.

The cross-sectional diameter of the conductive core may be 25 μm, the thickness of the insulator may be 30 μm, and the thickness of the shield thickness may be 3 μm. The cross-sectional diameter of the conductive core may be 50 μm, the thickness of the insulator may be 1.3 μm, and the thickness of the shield thickness may be 10 μm. The cross-sectional diameter of the conductive core may be 10 μm, the thickness of the insulator may be 14 μm, and the thickness of the shield thickness may be 3 μm. The cross-sectional diameter of the conductive core may be 7 μm, the thickness of the insulator may be 10 μm, and the thickness of the shield thickness may be 2 μm.

The conductive core may be formed from Cu or Cu/Ag alloy. The insulator may be formed from polyimide or Perfluoroalkoxy (PFA). The shield layer may be formed from Cu or Au.

In another general aspect, a method for reel-to-reel fabrication of micro-coaxial wire includes forming the micro-coaxial wire including receiving a core wire of the micro-coaxial wire with a dielectric layer deposited thereon, depositing a seed layer on the dielectric layer, depositing a shield layer on the seed layer, and winding the micro-coaxial wire onto a spool.

Aspects may include one or more of the following features.

The core wire may include a gold flashed copper wire. The dielectric layer may include a Parylene N material. Depositing the seed layer on the dielectric layer may include depositing a titanium layer and one or more of gold layer, a copper layer, and a silver layer onto the dielectric layer. Depositing the seed layer may include using a sputtering process. Depositing the seed layer may include depositing a nickel plating onto the dielectric using an electroless plating process. Depositing the shield layer may include electroplating a copper or gold material onto the seed layer. Depositing the seed layer may include passing the wire through a fixture. Receiving a core wire of the micro-coaxial wire with a dielectric layer deposited thereon may include de-spooling the wire.

In another general aspect, a method for reel-to-reel fabrication of micro-coaxial wire includes forming the micro-coaxial wire including receiving a core wire of the micro-coaxial wire from a spool, depositing a dielectric layer on the core wire, depositing a seed layer on the dielectric layer, depositing a shield layer on the seed layer, and winding the micro-coaxial wire onto a spool.

Aspects may include one or more of the following features.

The core wire may include a gold flashed copper wire. Depositing the dielectric layer on the core wire may include using a chemical vapor deposition process. The dielectric layer may include a Parylene N material. Depositing the seed layer on the dielectric layer may include depositing a titanium layer and one or more of gold layer, a copper layer, and a silver layer onto the dielectric layer. Depositing the seed layer may include using a sputtering process. Depositing the seed layer may include depositing a nickel plating onto the dielectric using an electroless plating process. Depositing the shield layer may include electroplating a copper or gold material onto the seed layer. Depositing the seed layer may include passing the wire through a fixture. Receiving the core wire may include de-spooling the wire.

In another general aspect, a system for reel-to-reel manufacturing of a micro-coaxial wire includes a first spool with a conductive core wire wound thereon, a dielectric deposition system configured to receive the core wire and to deposit a dielectric layer on the core wire, forming a dielectric coated core wire, a seed layer deposition system configured to receive the dielectric coated core wire and to deposit a seed layer on the dielectric coated core wire, forming a seed coated wire, a shield layer deposition system configured to receive the seed coated wire and to deposit a shield layer on the seed coated wire, forming a micro-coaxial wire, and a second spool configured to receive the micro-coaxial wire.

In some examples, application of a pure, solid, highly conductivity metal onto a wire is enabled by seeding a dielectric coated wire using one of the following methods: (a) CVD, (b) PVD, (c) Evaporation, (d) Sputtering, (e) chemically activating the surface using a process such as electroless Ni plating. “Pure” & “solid” are achieved by electroplating. “Highly conductive” has to do with the choice of plated metal, most commonly Au or Cu, but could also be Al, Ag, Pd, Sn, etc.

Other features and advantages of the invention are apparent from the following description, and from the claims.

### DESCRIPTION OF DRAWINGS

FIG. 1 is an electronic system including micro-coaxial wires.

FIG. 2 is a bare die based electronic system including micro-coaxial wires.

FIG. 3 is a first attachment strategy for the electronic system of FIG. 2.

FIG. 4 is a second attachment strategy for the electronic system of FIG. 2.

FIG. 5 is a third attachment strategy for the electronic system of FIG. 2.

FIG. 6 is a packaged component based electronic system including micro-coaxial wires.

FIG. 7 is a first attachment strategy for the electronic system of FIG. 6.

FIG. 8 is a second attachment strategy for the electronic system of FIG. 6.

FIG. 9 is a third attachment strategy for the electronic system of FIG. 6.

FIG. 10 is a through-via-perforated board based electronic system including micro-coaxial wires.

FIG. 11 is a first attachment strategy for the electronic system of FIG. 10.

FIG. 12 is a cross-sectional view of a micro-coaxial wire for power distribution.

FIG. 13 is a cross-sectional view of a micro-coaxial wire for signal distribution.

FIGS. 14a-14h show a bead-based micro-coaxial wire fabrication method.

FIGS. 15-17 show a fixture for fabrication of micro-coaxial wire.

FIGS. 18a-18e show a fixture-based micro-coaxial wire fabrication method.

FIGS. 19a-19i show a MEMS-based micro-coaxial wire fabrication method.

FIG. 20a and FIG. 20b show two views of the apparatus for feeding and layer removal of coaxial wires.

FIG. 21 shows transverse motion of rotating shafts.

FIG. 22a and FIG. 22b show the spinning cutting blade.

FIGS. 23a and 23b show the removal of layers from a coaxial wire using the apparatus.

FIG. 24 shows another embodiment of the apparatus.

FIG. 25 is a spool-based micro-coaxial wire attachment device.

FIG. 26 is a wire stripper of the device of FIG. 25.

FIG. 27 shows welding tips of the device of FIG. 25.

FIG. 28 shows shield attachment strategies employed by the device of FIG. 25.

FIG. 29 is an example of micro-coaxial wire constraints for a multi-chip package application.

FIG. 30 is an example of micro-coaxial wire constraints for a bare die package application.

FIG. 31 is an overview of number of coaxial wire configurations.

FIG. 32 shows a cross-sectional view of different micro-coaxial wires.

FIG. 33 is a graph of resistance vs core wire radius.

FIG. 34 is a graph of core radius vs. skin depth frequency and maximum transmission distance.

FIG. 35 is a graph of core radius vs. power delivery and copper fusing current.

FIGS. 36-38 show a number of exemplary micro-coaxial wire configurations.

FIG. 39 is a reel-to-reel wire fabrication system.

FIG. 40 is a sputtering fixture.

FIG. 41 is a foil wrapped shield.

### DESCRIPTION

### 1 Micro-Multi-Wire System

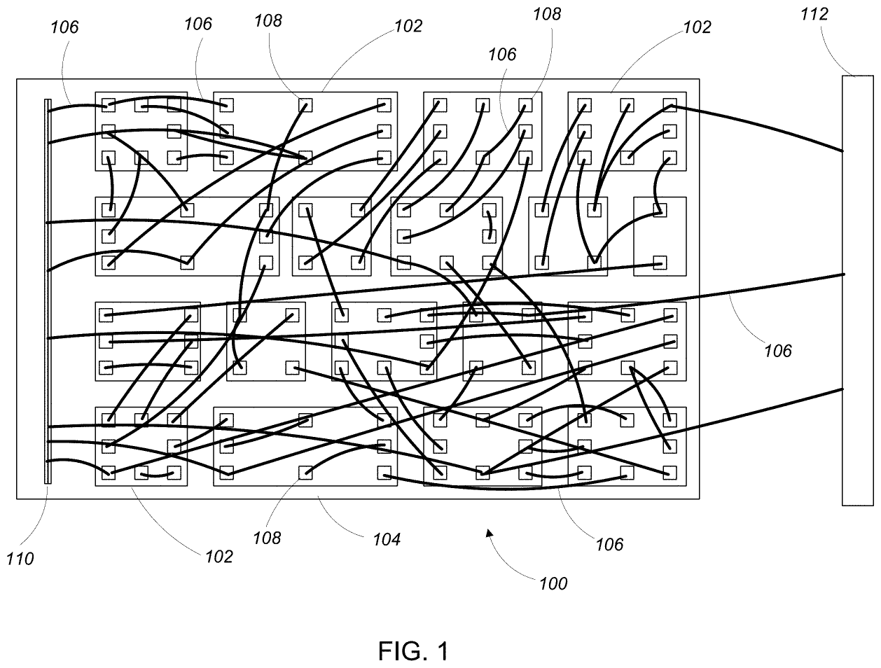

Referring to FIG. 1, an electronic system 100 replaces conductive traces and vias used to connect electrical components on conventional printed circuit boards with a micro-coaxial wiring system. The electronic system 100 includes a number of electronic components 102 (packaged integrated circuits, surface mountable ball grid array packaged integrated circuits, bare integrated circuits, etc.) attached to a substrate 104. Micro-coaxial wires 106 are used to connect connection points 108 (e.g., contact pads, solder balls of a ball grid array, etc.) on the electronic components 102 to connection points associated with a power supply 110, external devices 112, and to other connection points 108 on the same or other electronic components 102.

Given the large variation in electronic components available to engineers, a number of different strategies are employed to attach electronic components, to connection points associated with power supplies, external devices, and connection points on the same or other components, as is described in greater detail below.

### 1.1 Bare Die Based Micro-Multi-Wire System

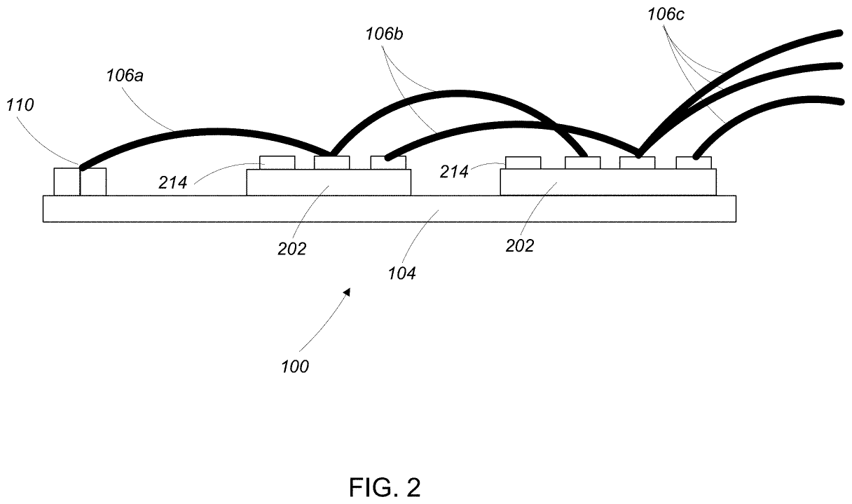

Referring to FIG. 2, in some examples, the electronic system 100 includes a number of bare dies (or ‘dice’) 202 attached to the substrate 104 (e.g., using an adhesive). Surfaces of the bare dies 202 facing away from the substrate 104 include contact pads 214 that are configured to be connected to one or more other connection points, external devices, and/or connection points associated with the power supply 110 using micro-coaxial wires 106 (as is described in greater detail below). For example, in the simple schematic diagram of FIG. 2, one or more first micro-coaxial wires 106a connect contact pads 214 of the bare dies 202 to connection points associated with the power supply 110, one or more second micro-coaxial wires 106b connect contact pads 214 of the bare dies 202 to other contact pads of the bare dies 202, and one or more third micro-coaxial wires 106c connect contact pads 214 of the bare dies 202 to one or more external devices or components.

### 1.1.1 Bare Die Attachment Strategy

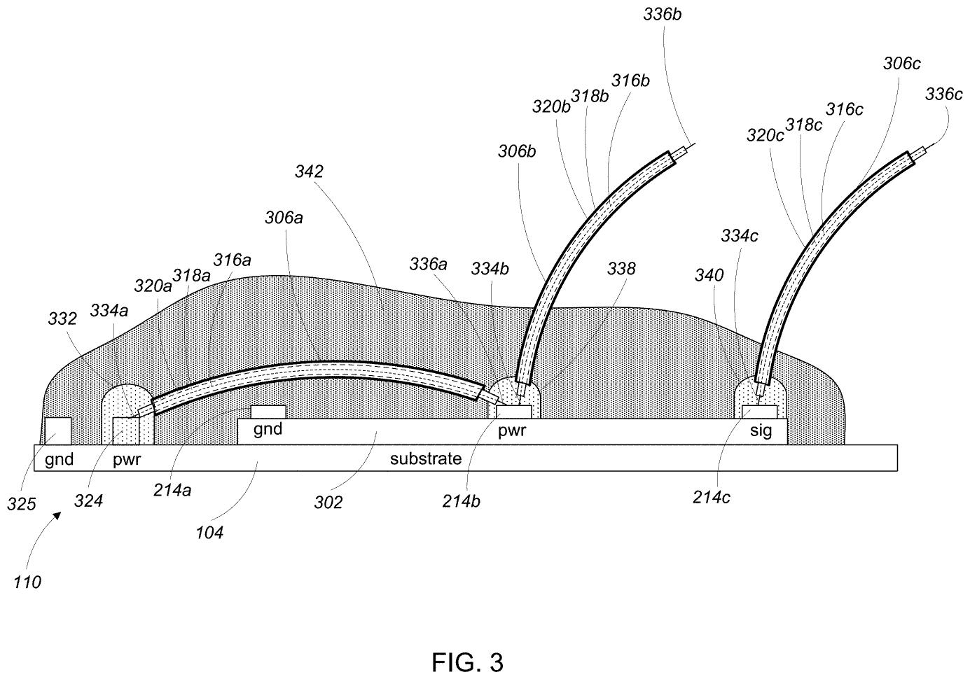

Referring to FIG. 3, a particular bare die 302 is attached to the substrate 104 and has its contact pads 214 connected to the power supply 110 using micro-coaxial wires according to an attachment strategy. The contact pads 214 are also connected to external devices (not shown) and to other connection points on other electronic components (not shown) using micro-coaxial wires according to the attachment strategy.

In the configuration of FIG. 3, there are three micro-coaxial wires 306 including a first micro-coaxial wire 306a, a second micro-coaxial wire 306b, and a third micro-coaxial wire 306c. The bare die 302 includes a ground (‘gnd’) contact pad 214a, a power (‘pwr’) contact pad 214b, and a signal (‘sig’) contact pad 214c.

In general, each of the micro-coaxial wires 306 includes a conductive inner core 316, an insulating layer 318, and a conductive outer shield 320. The conductive inner cores 316 of the micro-coaxial wires 306 are attached to contact pads 214 or other connection points 108 (e.g., a power (‘pwr’) connection point 324 associated with the power supply 110) and the conductive outer shield layers 320 of the micro-coaxial wires 106 are attached to a ‘gnd’ connection point 325 associated with the power supply 110, all while ensuring that the ‘gnd’ connection point 325 and the ‘pwr’ connection point 324 associated with the power supply 110 are not electrically connected (i.e., short circuited).

A first exposed portion 334a of the conductive inner core 316a of the first micro-coaxial wire 306a is attached to the ‘pwr’ connection point 324 associated with the power supply 110 and a second exposed portion 336a of the conductive inner core 316a of the first micro-coaxial wire 306a is attached to the ‘pwr’ contact pad 214b of the bare die 302. A first exposed portion 334b of the conductive inner core 316b of the second micro-coaxial wire 306b is attached to the ‘pwr’ contact pad 214b and a second exposed portion 336b of the conductive inner core 316b of the second micro-coaxial wire 306b is attached to another connection point or external device (not shown). A first exposed portion 334c of the conductive inner core 316c of the third micro-coaxial wire 306c is attached to the ‘sig’ contact pad 214c and a second exposed portion 336c of the conductive inner core 316c of the third micro-coaxial wire 306c is attached to another connection point or external device (not shown). In some examples, the connections between the conductive inner cores 316 and the various connection points are established using welding techniques (e.g., ultrasonic welding, electron beam welding, cold welding, laser welding, resistance welding, thermosonic capillary welding, or thermosonic wedge/peg welding) or soldering techniques.

Each connection between an exposed portion 334,336 of a conductive inner core 316 and a connection point is fully encased in an insulator. In the example of FIG. 3, the connection between the first exposed portion 334a of the conductive inner core 316a of the first micro-coaxial wire 306a and the ‘pwr’ connection point 324 is fully encased in a first insulator 332.

The connection between the second exposed portion 336a of the conductive inner core 316a of the first micro-coaxial wire 306a and the ‘pwr’ contact pad 214b is fully encased in a second insulator 338. The connection between the first exposed portion 334b of the conductive inner core 316b of the second micro-coaxial wire 306b and the ‘pwr’ contact pad 214b is also fully encased in the second insulator 338.

The connection between the first exposed portion 334c of the conductive inner core 316c of the third micro-coaxial wire 306c and the ‘sig’ contact pad 214c is fully encased in a third insulator 340.

In general, in the example of FIG. 3, the term “fully encased” by insulating material relates to both the exposed portion 334,336 of the conductive inner core 316 and the contact pad 214 or other connection point 108 being entirely covered by the insulating material, without any portion of the conductive inner core 316 and the contact pad 214 or other connection point 108 being left exposed. In general, an exposed part of the insulating layer 318 is also encased in the insulating material and a part of the conducting shield layer 320 may also be encased in the insulating material. One example of a suitable insulating material is a polyimide material. Of course, other suitable insulating polymers or other materials can be used.

A mass of conductive material 342 is deposited on the bare die 302 and the substrate 104, covering the ground (‘gnd’) connection point 325 associated with the power supply 110, the first insulator 332, the ‘gnd’ contact pad 214a of the bare die 302, the second insulator 338, and the third insulator 340. The mass of conductive material 342 establishes an electrical connection between the ‘gnd’ connection point 325 and the ‘gnd’ contact pad 214a of the bare die 302. The insulators 332, 338, 340 prevent a short circuit between the ‘gnd’ connection point 325 and the ‘pwr’ connection point 324, the ‘pwr’ contact pad 214b, or the ‘sig’ contact pad 214c from occurring.

The mass of conductive material 342 also fully encases the conductive shield layer 320a of the first micro-coaxial wire 306a, partially encases the conductive shield layer 320b of the second micro-coaxial wire 306b, and partially encases the conductive shield layer 320c of the third micro-coaxial wire 306c. As such, the mass of conductive material 342 is a ‘connector’ establishing an electrical connection between the ‘gnd’ connection point 325 and the conductive shield layers 320 of the micro-coaxial wires 306.

In general, the mass of conductive material 342 encases as much of the conductive shield layer as possible for all of the micro-coaxial wires. In some examples, there are 3 scenarios for in which the mass of conductive material 342 is used: (1) the mass 342 encases everything including all of the wires, insulation, chips, and power/gnd. (2) the mass 342 encases each chip 302 individually, making connection to a ground rail 325, and (3) a combination of (1) and (2).

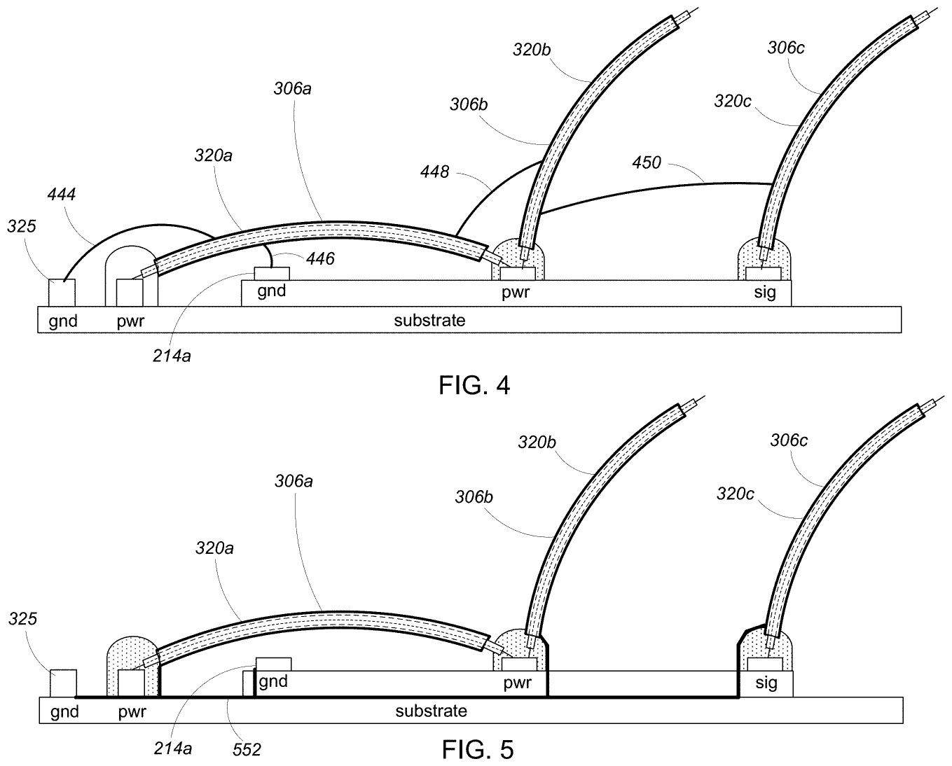

Referring to FIG. 4, in some examples fine wires (e.g., of the type used in wire bonding techniques) are used instead of the mass of conductive material 342 of FIG. 3 to establish an electrical connection between the ‘gnd’ connection point 325, the ‘gnd’ contact pad 214a of the bare die 302, and the conductive shield layers 320 of the micro-coaxial wires 306.

In particular, a first fine wire 444 connects the ‘gnd’ connection point 325 to the conductive shield layer 320a of the first micro-coaxial wire 306a. A second fine wire 446 connects the conductive shield layer 320a of the first micro-coaxial wire 306a to the ‘gnd’ contact pad 214a of the bare die 302. A third fine wire 448 connects the conductive shield layer 320a of the first micro-coaxial wire 306a to the conductive shield layer 320b of the second micro-coaxial wire 306b. A fourth fine wire 450 connects the conductive shield layer 320b of the second micro-coaxial wire 306b to the conductive shield layer 320c of the third micro-coaxial wire 306c.

Referring to FIG. 5, in some examples, one or more printed wires are used instead of the mass of conductive material 342 of FIG. 3 to establish an electrical connection between the ‘gnd’ connection point 325, the ‘gnd’ contact pad 214a of the bare die 302, and the conductive shield layers 320 of the micro-coaxial wires 306.

In particular, a printed wire 552 connects the ‘gnd’ connection point 325 to the conductive shield layer 320a of the first micro-coaxial wire 306a, the ‘gnd’ contact pad 214a of the bare die 302, the conductive shield layer 320b of the second micro-coaxial wire 306b, and the conductive shield layer 320c of the third micro-coaxial wire 306c.

### 1.2 Package Based Micro-Multi-Wire System

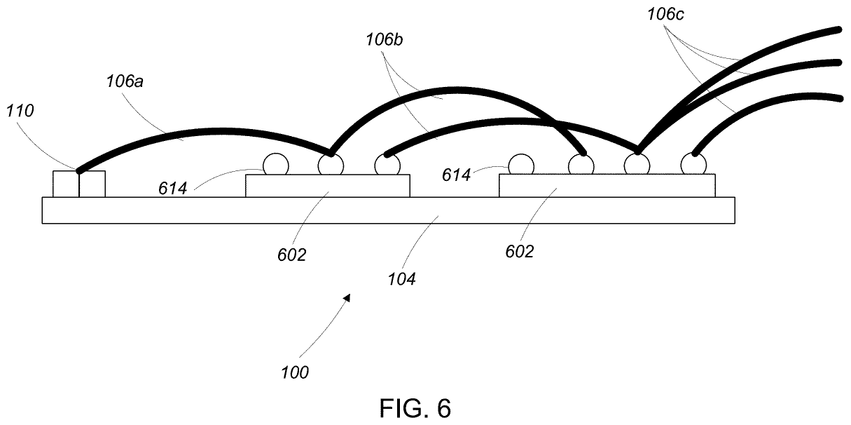

Referring to FIG. 6, in some examples, the electronic system 100 includes a number of packaged components 602 (e.g., ball grid array components, dual in-line packaged components, surface mount components, chip carriers, etc.) attached to the substrate 104 (e.g., using an adhesive). Surfaces of the packaged components 602 facing away from the substrate 104 include solder balls 614 (or other packaged component-specific connection points) that are configured to be connected to one or more other connection points, external devices, and/or the power supply 110 using micro-coaxial wires 106 (as is described in greater detail below). For example, in the simple schematic diagram of FIG. 6, one or more first micro-coaxial wires 106a connect solder balls 614 of the packaged components 602 to the power supply 110, one or more second micro-coaxial wires 106b connect solder balls 614 of the packaged components 602 to other solder balls 614 of the packaged components 602, and one or more third micro-coaxial wires 106c connect solder balls 614 of the packaged components 602 to one or more external devices or components (not shown).

### 1.2.1 Packaged Component Attachment Strategy

Referring to FIG. 7, a particular packaged component 702 is attached to the substrate 104 and has its solder balls 614 connected to the power supply 110 using micro-coaxial wires according to an attachment strategy. The solder balls 614 are also connected to external devices (not shown) and to other connection points on other electronic components (not shown) using micro-coaxial wires according to an attachment strategy.

In the configuration of FIG. 7, there are three micro-coaxial wires including a first micro-coaxial wire 706a, a second micro-coaxial wire 706b, and a third micro-coaxial wire 706c. The packaged component 702 includes a ground (‘gnd’) solder ball 614a, a power (‘pwr’) solder ball 614b, and a signal (‘sig’) solder ball 614c.

In general, each of the micro-coaxial wires 706 includes a conductive inner core 716, an insulating layer 718, and a conductive outer shield 720. The conductive inner cores 716 of the micro-coaxial wires 706 are attached to contact pads 614 or other connection points 108 (e.g., a power (‘pwr’) connection point 724 associated with the power supply 110) and the conductive outer shield layers 716 of the micro-coaxial wires 706 are attached to the ‘gnd’ connection point 725 associated with the power supply 110, all while ensuring that the ‘gnd’ connection point 725 and the ‘pwr’ connection point 724 associated with the power supply are not electrically connected (i.e., short circuited).

A first exposed portion 734a of the conductive inner core 716a of the first micro-coaxial wire 706a is attached to the ‘pwr’ connection point 724 associated with the power supply 110 and a second exposed portion 736a of the conductive inner core 716a of the first micro-coaxial wire 706a is attached to the ‘pwr’ solder ball 614b of the packaged component 702. A first exposed portion 734b of the conductive inner core 716b of the second micro-coaxial wire 706b is attached to the ‘pwr’ solder ball 614b and a second exposed portion 736b of the conductive inner core 716b of the second micro-coaxial wire 706b is attached to another connection point or external device (not shown). A first exposed portion 734c of the conductive inner core 716c of the third micro-coaxial wire 706c is attached to the ‘sig’ solder ball 614c and a second exposed portion 736c of the conductive inner core 716c of the third micro-coaxial wire 706c is attached to another connection point or external device (not shown). In some examples, the connections between the conductive inner cores 716 and the various connection points are established using welding techniques (e.g., ultrasonic welding, electron beam welding, cold welding, laser welding, resistance welding, thermosonic capillary welding, or thermosonic wedge/peg welding) or soldering techniques. Note that, in some examples, one or more interposer pads 735 are attached to the solder balls 614 to facilitate a reliable connection between the exposed portions 734,736 of the conductive inner cores 716 and the solder balls 614.

Each connection between an exposed portion 734,736 of a conductive inner core 716 and a connection point is fully encased in an insulating material. In the example of FIG. 7, the connection between the first exposed portion 734a of the conductive inner core 716a of the first micro-coaxial wire 706a and the ‘pwr’ connection point 724 is fully encased in a first insulator 732.

The connection between the second exposed portion 736a of the conductive inner core 716a of the first micro-coaxial wire 706a and the ‘pwr’ solder ball 614b is fully encased in a second insulator 738. The connection between the first exposed portion 734b of the conductive inner core 716b of the second micro-coaxial wire 706b and the ‘pwr’ solder ball 614b is also fully encased in the second insulator 738. In this example, the connection between the first exposed portion 734c of the conductive inner core 716c of the third micro-coaxial wire 706c and the ‘sig’ solder ball 614c is also fully encased in the second insulator 738.

As was the case in previous examples, the term “fully encased” by insulating material relates to both the exposed portion 734,736 of the conductive inner core 716 and the solder ball 614 or other connection point 108 being entirely covered by the insulating material, without any portion of the conductive inner core 716 and the solder ball 614 or other connection point 108 being left exposed. In general, an exposed part of the insulating layer 718 of the micro-coaxial wire 706 is also encased in the insulating material and a part of the conducting shield layer 720 of the micro-coaxial wire 706 may also be encased in the insulating material. One example of a suitable insulating material is a polyimide material. Of course, other suitable insulating polymers can be used.

A mass of conductive material 742 is deposited on the packaged component 702 and the substrate 104, covering the ground (‘gnd’) connection point 725 associated with the power supply 110, the first insulator 732, the ‘gnd’ solder ball 614a of the packaged component 702 and the second insulator 738. The mass of conductive material 742 establishes an electrical connection between the ‘gnd’ connection point 725 and the ‘gnd’ solder ball 614a of the packaged component 702. The insulators 732, 738 prevent a short circuit between the ‘gnd’ connection point 725 and the ‘pwr’ connection point 724, the ‘pwr’ solder ball 614b, or the ‘sig’ contact pad 614c from occurring.

The mass of conductive material 742 also fully encases the conductive shield layer 720a of the first micro-coaxial wire 706a, partially encases the conductive shield layer 720b of the second micro-coaxial wire 706b, and partially encases the conductive shield layer 720c of the third micro-coaxial wire 706c. As such, the mass of conductive material 742 is a ‘connector,’ establishing an electrical connection between the ‘gnd’ connection point 725 and the conductive shield layers 720 of the micro-coaxial wires 706.

In general, the mass of conductive material 742 encases as much of the conductive shield layer as possible for all of the micro-coaxial wires. In some examples, there are 3 scenarios for in which the mass of conductive material 742 is used: (1) the mass 742 encases everything including all of the wires, insulation, chips, and power/gnd. (2) the mass 742 encases each component 702 individually, making connection to a ground rail 725, and (3) a combination of (1) and (2).

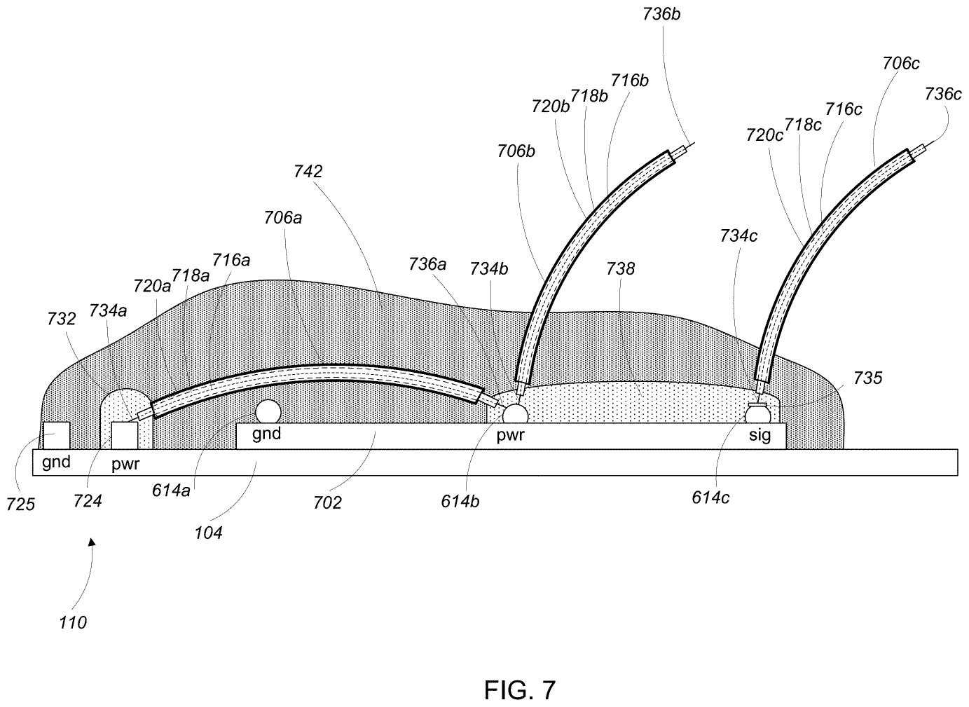

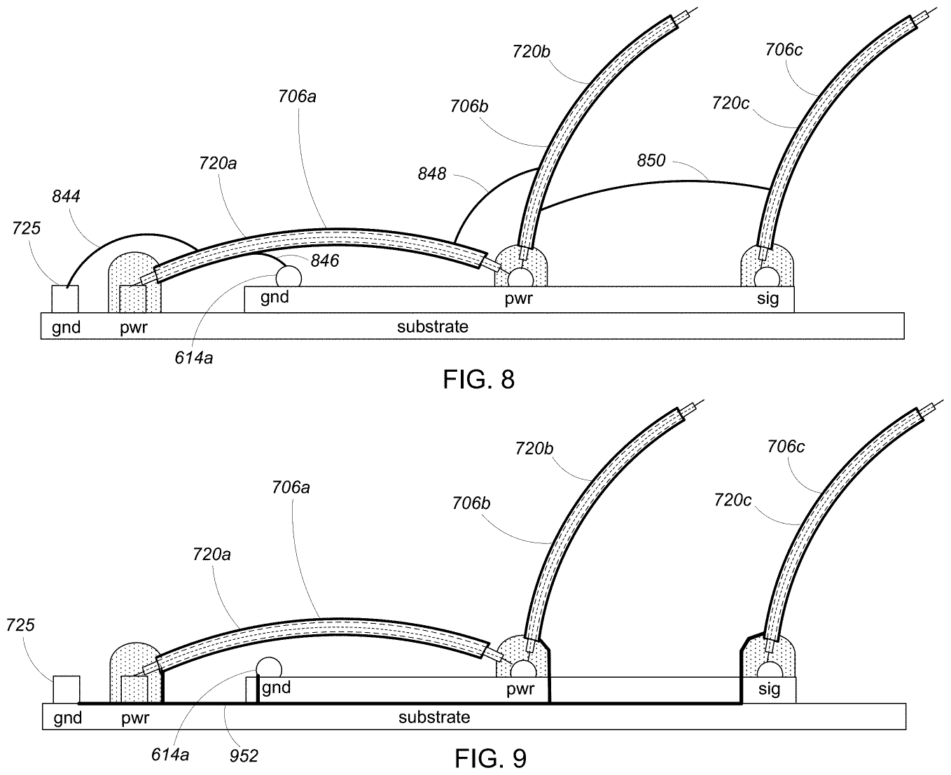

Referring to FIG. 8, in some examples fine wires (e.g., of the type used in wire bonding techniques) are used instead of the mass of conductive material 742 of FIG. 7 to establish an electrical connection between the ‘gnd’ connection point 725, the ‘gnd’ solder ball 614a of the packaged component 702, and the conductive shield layers 720 of the micro-coaxial wires 706.

In particular, a first fine wire 844 connects the ‘gnd’ connection point 725 to the conductive shield layer 720a of the first micro-coaxial wire 706a. A second fine wire 846 connects the conductive shield layer 720a of the first micro-coaxial wire 706a to the ‘gnd’ solder ball 614a of the packaged component 702. A third fine wire 848 connects the conductive shield layer 720a of the first micro-coaxial wire 706a to the conductive shield layer 720b of the second micro-coaxial wire 706b. A fourth fine wire 850 connects the conductive shield layer 720b of the second micro-coaxial wire 706b to the conductive shield layer 720c of the third micro-coaxial wire 706c.

Referring to FIG. 9, in some examples, one or more printed wires are used instead of the mass of conductive material 742 of FIG. 7 to establish an electrical connection between the ‘gnd’ connection point 725, the ‘gnd’ solder ball 614a of the packaged component 702, and the conductive shield layers 720 of the micro-coaxial wires 706.

In particular, a printed wire 952 connects the ‘gnd’ connection point 725 to the conductive shield layer 720a of the first micro-coaxial wire 706a, the ‘gnd’ solder ball 614a of the packaged component 702, the conductive shield layer 720b of the second micro-coaxial wire 706b, and the conductive shield layer 720c of the third micro-coaxial wire 706c.

### 1.3 Through-Via-Perforated (TVP) Board Based Micro-Multi-Wire System

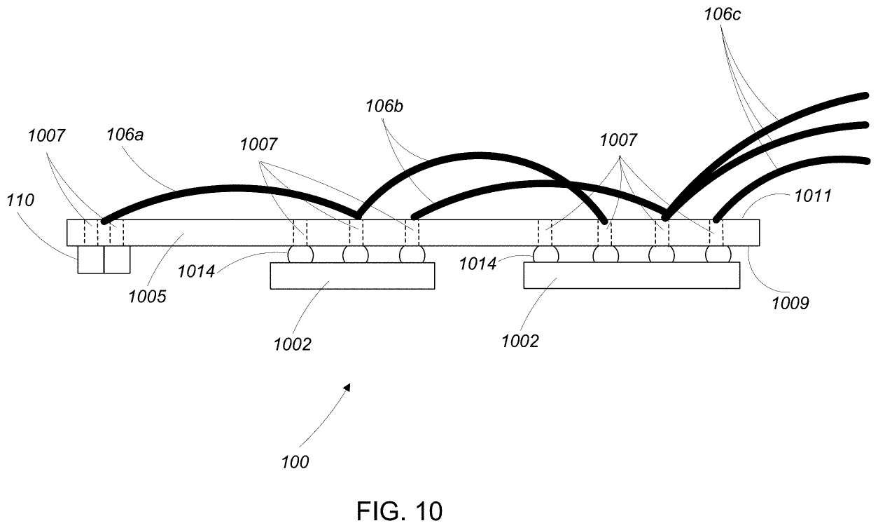

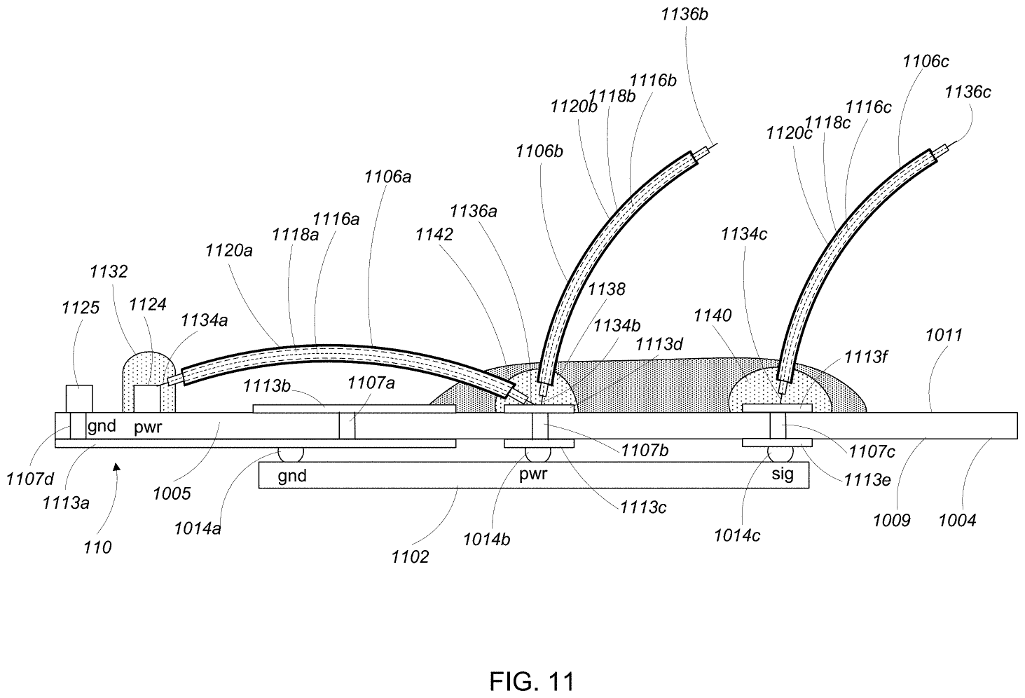

Referring to FIG. 10, in some examples, the electronic system 100 includes a number of components such as bare dies or packaged components 1002 (e.g., ball grid array components, dual in-line packaged components, surface mount components, chip carriers, etc.) assembled on a Through-Via-Perforated (TVP) board 1004. In general, a TVP board 1004 includes an insulating substrate 1005 with a number of vias 1007 extending therethrough. The vias 1007 are filled with a conductive material (e.g., solder) and may be connected to electrically conductive contact pads (see FIG. 11) or plates on a first side 1009 and/or a second side 1011 of the substrate 1005. The packaged components 1002 (or in some examples, bare dies) are positioned on the first side 1009 of the TVP board 1004 and include solder balls 1014 (or other packaged component-specific connection points) that are aligned with and joined (e.g., soldered) to the vias 1007 and their associated electrically conductive contact pads or plates.

On the second side 1011 of the TVP board 1004, the vias 1007 and their associated electrically conductive contact pads or plates are configured to be connected to one or more other connection points (e.g., vias), external devices, and/or the power supply 110 using micro-coaxial wires 106 (as is described in greater detail below). For example, in the simple schematic diagram of FIG. 10, one or more first micro-coaxial wires 106a connect vias 1007 connected to the packaged components 1002 to the power supply 110, one or more second micro-coaxial wires 106b connect vias 1007 connected to the packaged components 1002 to other vias 1007 of the packaged components 1002, and one or more third micro-coaxial wires 106c connect vias connected to the packaged components 1002 to one or more external devices or components (not shown).

### 1.3.1 Through-Via-Perforated Board Attachment Strategy

Referring to FIG. 11, a TVP board 1004 includes a power supply 110 and four vias. The power supply has a power (‘pwr’) connection point 1124 and a ground (‘gnd’) connection point 1125. A first via 1107d of the TVP board 1004 is connected to the ‘gnd’ connection point 1125 on the second side 1011 of the TVP board 1004 and to a first electrically conductive plate 1113a on the first side 1009 of the TVP board 1004. As a result, electrical signals can travel between the ‘gnd’ connection point 1125 and the first electrically conductive plate 1113a by way of the first via 1107d.

A second via 1107a is connected to the first electrically conductive plate 1113a on the first side 1009 of the TVP board 1004 and to a second electrically conductive plate 1113b on the second side 1011 of the TVP board 1004. As a result, electrical signals can travel between the first electrically conductive plate 1113a and the second electrically conductive plate 1113b by way of the second via 1107a.

A third via 1107b is connected to a third electrically conductive plate 1113c on the first side 1009 of the TVP board 1004 and to a fourth electrically conductive plate 1113d on the second side 1011 of the TVP board 1004. As a result, electrical signals can travel between the third electrically conductive plate 1113c and the fourth electrically conductive plate 1113d by way of the third via 1107b.

A fourth via 1107d is connected to a fifth electrically conductive plate 1113e on the first side 1009 of the TVP board 1004 and to a sixth electrically conductive plate 1113f on the second side 1011 of the TVP board. As a result, electrical signals can travel between the fifth electrically conductive plate 1113e and the sixth electrically conductive plate 1113f by way of the fourth via 1107c.

A particular packaged component 1102 is attached to the first side 1009 of the TVP board 1004 with each of its solder balls 1014 attached to a via 1007 by way of an electrically conductive plate 1113. In particular, a ground ‘gnd’ solder ball 1014a is attached to the first electrically conductive plate 1113a (and is therefore connected to the first via 1107d and the second via 1107a). A power ‘pwr’ solder ball 1014b is attached to the third electrically conductive plate 1113c (and is therefore connected to the third via 1107b). A signal ‘sig’ solder ball 1014c is attached to the fifth electrically conductive plate 1113e (and is therefore connected to the fourth via 1107c). It is noted that connections from the components to the vias don't necessarily need to use a solder ball. In some examples, solder is used for packaged components and other connection types are used for die (e.g. Cu oxide bonds or C4 bumps).

With the packaged component 1102 attached to the TVP board 1004, an attachment strategy is employed to connect the vias 1107 to the power supply 110, external devices 112 (not shown), and to other connection points 108 on other electronic components (not shown) using micro-coaxial wires.

In general, each of the micro-coaxial wires 1106 includes a conductive inner core 1116, an insulating layer 1118, and a conductive outer shield 1120. The conductive inner cores 1116 of the micro-coaxial wires 1106 are connected to contact pads 1014 or other connection points 108 (e.g., the power (‘pwr’) connection point 1124 associated with the power supply 110) and the conductive outer shield layers 1120 of the micro-coaxial wires 1106 are connected to the ‘gnd’ connection point 1125 associated with the power supply 110, all while ensuring that the ‘gnd’ connection point 1125 and the ‘pwr’ connection point 1124 associated with the power supply are not electrically connected (i.e., short circuited).

In the configuration of FIG. 11, there are three micro-coaxial wires including a first micro-coaxial wire 1106a, a second micro-coaxial wire 1106b, and a third micro-coaxial wire 1106c

A first exposed portion 1134a of the conductive inner core 1116a of the first micro-coaxial wire 1106a is attached to the ‘pwr’ connection point 1124 associated with the power supply 110 and a second exposed portion 1136a of the conductive inner core 1116a of the first micro-coaxial wire 1106a is attached to the fourth electrically conductive plate 1113d (and therefore to the ‘pwr’ solder ball 1014b of the packaged component 1102 by way of the third via 1107b and the third electrically conductive plate 1113c).

A first exposed portion 1134b of the conductive inner core 1116b of the second micro-coaxial wire 1106b is attached to the fourth electrically conductive plate 1113d (and therefore to the ‘pwr’ solder ball 1014b of the packaged component 1102 by way of the third via 1107b and the third electrically conductive plate 1113c). A second exposed portion 1136b of the conductive inner core 1116b of the second micro-coaxial wire 1106b is attached to another connection point or external device (not shown).

A first exposed portion 1134c of the conductive inner core 1116c of the third micro-coaxial wire 1106c is attached to the sixth electrically conductive plate 1113f (and therefore to the ‘sig’ solder ball 1014c of the packaged component 1102 by way of the fifth via 1107c and the third electrically conductive plate 1113e). A second exposed portion 1136c of the conductive inner core 1116c of the third micro-coaxial wire 1106c is attached to another connection point or external device (not shown).

In some examples, the connections between the conductive inner cores 716 and the various connection points are established using welding techniques (e.g., ultrasonic welding, electron beam welding, cold welding, laser welding, resistance welding, thermosonic capillary welding, or thermosonic wedge/peg welding) or soldering techniques.

Each connection between an exposed portion 1134,1136 of a conductive inner core 1116 and a connection point is fully encased in an insulating material.

In the example of FIG. 11, the connection between the first exposed portion 1134a of the conductive inner core 1116a of the first micro-coaxial wire 1106a and the ‘pwr’ connection point 1124 is fully encased in a first insulator 1132. The connection between the second exposed portion 1136a of the conductive inner core 1116a of the first micro-coaxial wire 1106a and the fourth electrically conductive plate 1113d is fully encased in a second insulator 1138.

The connection between the first exposed portion 1134b of the conductive inner core 1116b of the second micro-coaxial wire 1106b and the fourth electrically conductive plate 1113d is fully encased in the second insulator 1138.

The connection between the first exposed portion 1134c of the conductive inner core 1116c of the third micro-coaxial wire 1106c and the sixth electrically conductive plate 1113f is fully encased in a third insulator 1140.

As was the case in previous examples, the term “fully encased” by insulating material relates to both the exposed portion 1134/1136 of the conductive inner core 1116 and the solder ball 1014 or other connection point 108 being entirely covered by the insulating material, without any portion of the conductive inner core 1116 and the solder ball 1014 or other connection point 108 being left exposed. In general, an exposed part of the insulating layer 1118 of the micro-coaxial wire 1106 is also encased in the insulating material and a part of the conducting shield layer 1120 of the micro-coaxial wire 1106 may also be encased in the insulating material. One example of a suitable insulating material is a polyimide material. Of course, other suitable insulating polymers can be used.

A mass of conductive material 1142 is deposited on the second side 1011 of the TVP board 1004, partially covering the second electrically conductive plate 1113b, the first insulator 1138, and the second insulator 1140. The mass of conductive material 742 also partially encases the conductive shield layer 1120a of the first micro-coaxial wire 1106a, partially encases the conductive shield layer 1120b of the second micro-coaxial wire 1106b, and partially encases the conductive shield layer 1120c of the third micro-coaxial wire 1106c. As such, the mass of conductive material 1142 is a ‘connector,’ establishing an electrical connection between the ‘gnd’ connection point 1125 and the conductive shield layers 1120 of the micro-coaxial wires 1106 (by way of the mass of conductive material 1142, the second electrically conductive plate 1113b, the second via 1107a, the first electrically conducting plate 1113a, and the first via 1107d).

The insulators 1132, 1138, 1140 prevent a short circuit between the ‘gnd’ connection point 1125 and the ‘pwr’ connection point 1124, the ‘pwr’ solder ball 1014b, or the ‘sig’ contact pad 1014c from occurring.

In general, the mass of conductive material 1142 encases as much of the conductive shield layer as possible for all of the micro-coaxial wires. In some examples, the mass of conductive material 1142 extends to encase the ‘gnd’ connection point 1125. In some examples, the mass of conductive material 1142 coats substantially the entire second side 1011 of the TVP board 1004.

### 1.4 Miscellaneous

In some examples, the mass of conductive material described in the examples above is a metallic material that is deposited by flowing the material (e.g., flowing melted solder). In some examples, the mass of conductive material described in the examples above is a metallic material that is deposited by spray coating the material. In some examples, the mass of conductive material described in the examples above is a metallic material that is deposited by vapor depositing the material. In some examples, the mass of conductive material described in the examples above is a metallic material that is deposited by sputtering the material. In some examples, the mass of conductive material described in the examples above is a metallic material that is deposited by plating (e.g., electroplating or electroless plating) the material.

In some examples, insulating materials are dispensed from a needle or using a jet printing technique. In some examples, the conductive mass of material is dispensed from a needle or by using a jet printing technique. In some examples, the insulating materials include epoxy materials to ensure that the bond of the wire to the connection point is stronger than the wire itself.

In some examples, the electrically insulating material described in the examples above is deposited by flowing the material into place. In some examples, the electrically insulating material described in the examples above is deposited by vapor depositing the material into place. In some examples, the electrically insulating material includes a polymeric material. In some examples, the electrically insulating material described in the examples above is deposited by aerosol jetting the material into place.

In some examples, electrically conductive connections are established using conductive adhesives.

In some examples, micro-multi-wire systems include combinations of two or more of the configurations and attachments strategies described above.

### 2 Micro-Coaxial Wires

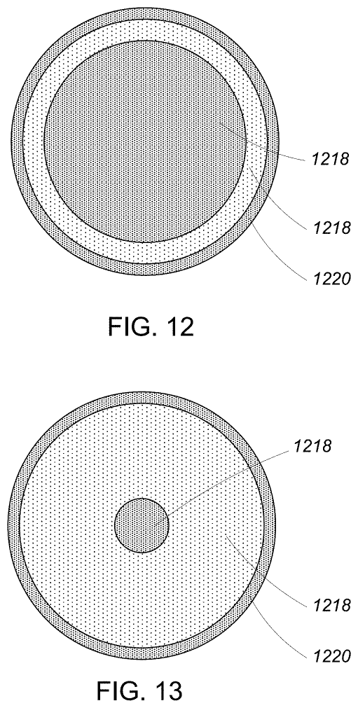

Referring to FIGS. 12 and 13, in some examples, the micro-coaxial wires used in the above-described systems have specific properties based on the type of signal that they are designed to carry. Examples of such micro-coaxial wires include micro-coaxial wires for power distribution and micro-coaxial wires for signal distribution.

### 2.1 Micro-Coaxial Wires for Power Distribution

Referring to FIG. 12, a cross-sectional view of a micro-coaxial wire for power distribution includes an electrically conductive shield layer 1220, an electrically insulating layer 1218, and an electrically conductive core 1216. Current is carried down the electrically conductive core 1216 and returns via the electrically conductive shield 1220.

In general, the micro-coaxial wire for power distribution is designed to have low resistance, low inductance, and low impedance, and high capacitance. In general, the resistance, inductance, impedance, and capacitance values of the micro-coaxial wires vary widely depending on the chips to which the wires are being attached. Inductance and resistance should be as close to zero as possible (at least in the case of power micro-coaxial wires). Theoretical limits (simulated) show that the inductance of the wires can be as low as 20 pH/mm. In one example, a micro-coaxial wire has an impedance in the milliohm range.

To achieve these properties, the electrically conductive core occupies a large percentage of the cross-sectional area of the wire. For example, given a 15 μm diameter micro-coaxial wire for power distribution, the electrically conductive core 1216 has, for example, a 10 μm diameter, the electrically conductive shield layer 1220 has the same cross-sectional area as the electrically conductive core 1216, and the electrically insulating layer 1218 has a thickness of 1 μm.

In general, the thickness of the electrically conductive core 1216 is defined by the amount of power distributed to the chip. The thickness of the insulating layer 1218 is as small as possible to minimize impedance in the wire. In some examples, the electrically conductive shield layer 1220 is designed to be at least as conductive as the electrically conducive core 1216. In some examples, the electrically conductive core 1216 has a 127 μm diameter when being used to connect packaged components and has a 11.4 μm diameter when being used to make chip-level connections (i.e., bare die connections). In some examples, the insulating layer 1218 has a thickness in a range of 0.1 μm to 5 μm when being used to connect packaged components and has a thickness less than 1 μm when being used to make chip-level connections.

### 2.2 Micro-Coaxial Wires for Signal Distribution

Referring to FIG. 13, a cross-sectional view of a micro-coaxial wire for signal distribution includes an electrically conductive shield layer 1320, an electrically insulating layer 1318, and an electrically conductive core 1316.

In general, the micro-coaxial wire for signal distribution is designed to have a resistance in a range of 30 to 75-Ohms. For example, certain micro-coaxial wires for signal distribution are designed to have a 50-Ohm resistance. The electrically insulating layer 1318 is thick relative to the electrically insulating layer of the micro-coaxial wire for power distribution and the diameter of the electrically conductive core 1316 is small relative to the electrically conductive core of the micro-coaxial wire for power distribution.

### 2.3 Micro-Coaxial Wire Fabrication

Given the small size of the micro-coaxial wires used in the systems described above, a number of non-conventional micro-coaxial wire fabrication techniques are used to make the wires.

### 2.3.1 Bead Based Fabrication

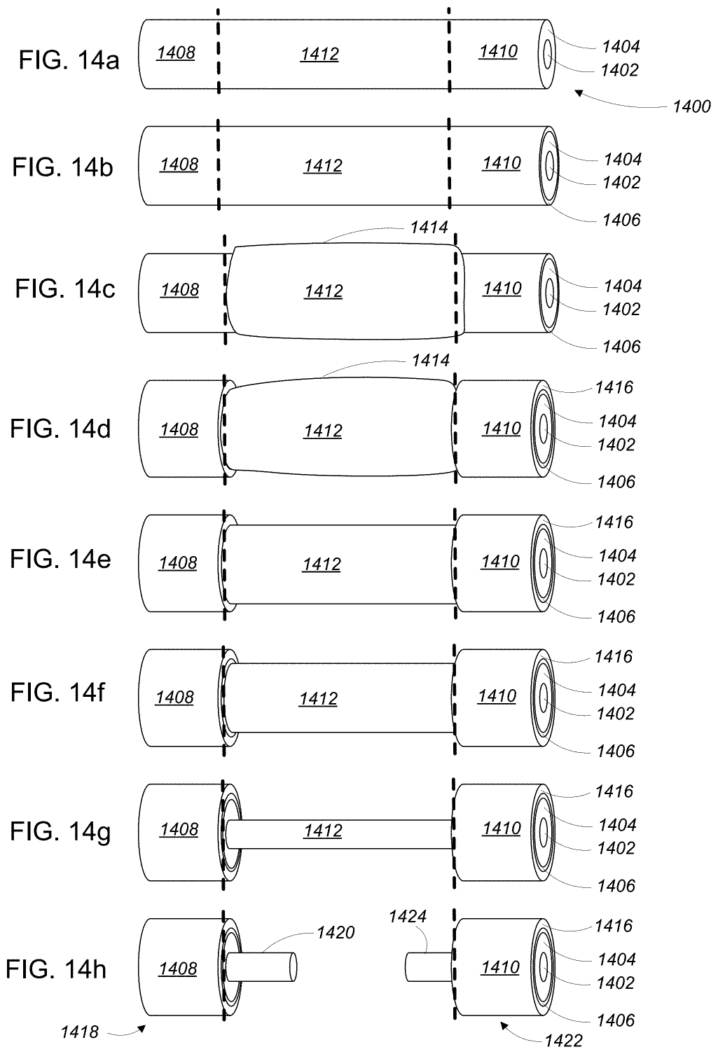

Referring to FIGS. 14a-14h a bead based micro-coaxial wire fabrication method fabricates two (or more) lengths of micro-coaxial wire, each length having a portion of its conductive inner core exposed.

Referring to FIG. 14a, the fabrication method begins by receiving a length of insulated wire 1400. The length of insulated wire includes an electrically conductive inner core 1402 surrounded by an electrically insulating layer 1404. To aid in the explanation of the fabrication method, the insulated wire 1400 is described as having three segments, a first segment 1408, a second segment 1410, and a third segment 1412 disposed between the first segment 1408 and the second segment 1410.

Referring to FIG. 14b, after receiving the length of insulated wire 1400, an adhesion layer 1406 is deposited on the electrically insulating layer 1404 over the length of insulated wire 1400 (i.e., on the first segment 1408, the second segment 1410, and the third segment 1412). In general, the adhesion layer serves to facilitate adhesion of an electroplated material to the insulated wire (as is described in detail below).

Referring to FIG. 14c, after deposition of the adhesion layer 1406, a masking bead 1414 is deposited on the adhesion layer 1406 in the third segment 1412. The masking bead 1414 prevents adhesion of an electroplated material to the third segment 1412. In some examples, the masking bead 1414 is formed of a polymeric material and is deposited by a needle, spray, sputter, or jet based deposition method.

Referring to FIG. 14d, after deposition of the masking bead 1414, an electrically conductive shield layer 1416 is deposited on the first segment 1408 and the second segment 1410 (but not the third segment 1412, due to the presence of the masking bead 1414).

Referring to FIG. 14e, after deposition of the electrically conductive shield layer 1416, the masking bead 1414 is removed from the third segment 1412. In some examples, the masking bead 1414 is removed using a laser cutting/etching procedure. In some examples, the masking bead 1414 is removed from the third segment 1412 using a chemical removal procedure, wherein the masking bead 1414 is formed form a photoresist or nail-polish like material and removal of the masking bead 1414 includes dipping the masking bead 1414 in a bath of photoresist remover or acetone. In some examples, the masking bead 1414 (and possibly a portion of the dielectric material) is thermally removed.

Referring to FIG. 14f, the adhesion layer 1406 is removed from the third segment 1412. In some examples, the adhesion layer 1406 is removed after removal of the masking bead 1414 from the third segment 1412. In some examples, the adhesion layer 1406 is removed at the same time that the masking bead 1414 is removed from the third segment 1412. In some examples, the adhesion layer 1406 is removed using a laser cutting/etching procedure. In some examples, the adhesion layer 1406 is removed using a wet etch (e.g., Au, Cu, Ti etchant chemistries).

Referring to FIG. 14g, the electrically insulating layer 1404 of the insulated wire 1400 is removed from the third segment 1412, exposing the electrically conductive core 1402 in the third segment 1412. In some examples, the electrically insulating layer 1404 is removed using a laser cutting/etching procedure. In some examples, the electrically insulating layer 1404 is thermally removed. In some examples, when the electrically insulating layer 1404 is particularly thin, the adhesion layer 1406 doesn't need to be explicitly removed.

Referring to FIG. 14h, the electrically conductive core 1402 in the third segment 1412 is bisected (e.g., using a wire cutter or a blade), creating a first length of micro-coaxial wire 1418 with a first exposed section 1420 of electrically conductive core 1402 and a second length of micro-coaxial wire 1422 with a second exposed section 1424 of electrically conductive core 1402.

In general, the procedure above can be used to generate any number of lengths of micro-coaxial wire from a length of insulated wire. Furthermore, the lengths of the micro-coaxial wires generated by the fabrication procedure can be specified (by bead placement) to meet the needs of a given application.

### 2.3.2 Fixture Based Fabrication

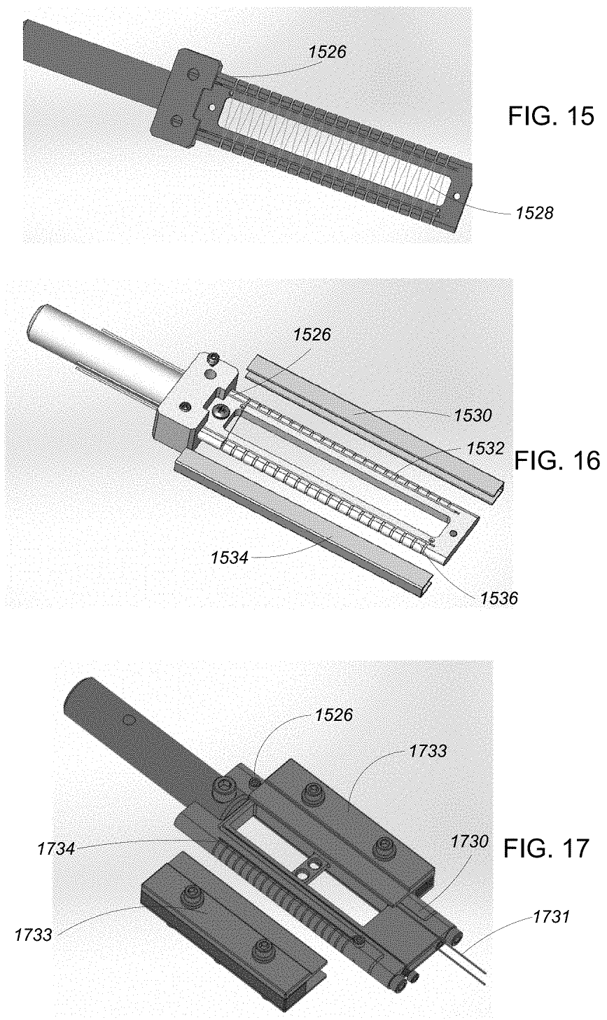

Referring to FIGS. 15-17, in some examples, micro-coaxial wires are fabricated using a specialized fixture.

Referring to FIG. 15, the fixture includes a spool 1526 onto which a length of insulated wire 1528 is wound. Referring to FIG. 16, once the length of insulated wire 1528 is wound onto the spool 1526, a first masking member 1530 is placed over a first edge 1532 of the spool 1526 such that portions of the insulated wire 1528 on the first edge 1532 of the spool 1526 are covered by the first masking member 1530. A second masking member 1534 is placed over a second edge 1536 of the spool 1526 such that portions of the insulated wire 1528 on the second edge 1536 of the spool 1526 are covered by the second masking member 1534. In some examples, with the first masking member 1530 and the second masking member 1534 attached to the spool 1526 of the fixture, the fixture undergoes a plating seed layer deposition. The seed layer deposition happens only on the portion of the wire 1528 between the first edge 1532 and second edge 1536 of the spool 1526. After seed layer deposition, the masking members 1530 and 1534 are removed. The seed layer is only deposited on unmasked portions of the wire 1528.

In one example, the seed material is a layer of Ti for adhesion to the dielectric and a layer of Au on top of the Ti. This is a seed for Au plating. In another example, the seed material is a layer of Ti for adhesion to the dielectric and a layer of Cu on top of the Ti. This is a seed for Cu plating. In another example, the seed could be a Cu/Mn alloy as a seed for Cu plating. In another example the seed could be Pt in preparation for Ni, Au or Cu plating. The seed layer can be deposited in a sputtering tool, evaporation tool, ALD (atomic layer deposition) tool, or CVD (chemical vapor deposition) tool. After the deposition process, masking members 1530 and 1534 are removed from the fixture.

In general, a distance between the first edge 1532 of the spool 1526 and the second edge 1536 of the spool 1526 determines a length of the micro-coaxial wires that are fabricated using the fixture.

Referring to FIG. 17, the fixture is configured to perform an electroplating procedure on portions of the insulated wire that are not masked (e.g. by the first and second masking members 1530, 1534), as is described in greater detail below.

For electroplating, a second set of masking members 1730, 1734 are attached to the fixture 1526. Additionally, the plating contact, a conductive wire 1731, is attached. Clamping members 1733 are placed on the second set of masking members 1730, 1734 and apply pressure on the conductive plating bath contact creating an electrical connection between the seed layer that was deposited in the previous step on 1528, to the electrical source that provides the electrical potential for plating the segments of the wire between edges 1532 and 1536. Once these new items are attached to the spool 1526, the fixture can be inserted into the plating bath for plating. Plated materials include, but are not limited to Cu, Au, Ni, Solder.

Once the electroplating procedure is complete, the masking member 1530, 1534 can be removed and the micro-coaxial wires are formed by cutting the wires in the area where no electroplating occurred (e.g., the masked areas of the wire).

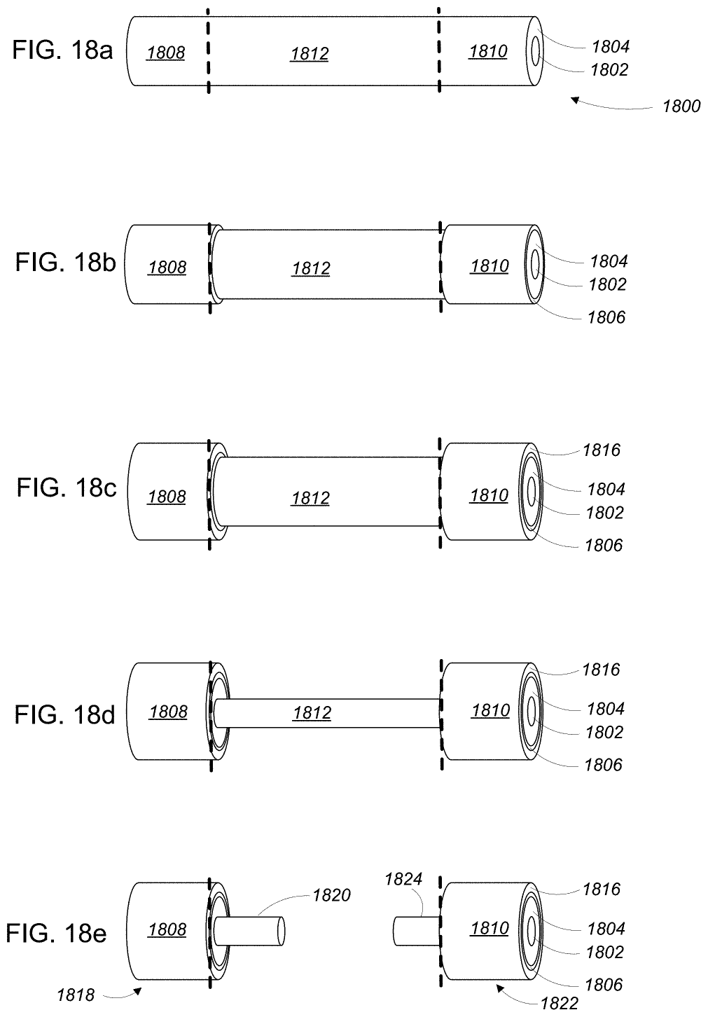

Referring to FIGS. 18a-18e, the fixture-based micro-coaxial wire fabrication procedure is explained in detail.

Referring to FIG. 18a, the fabrication method begins by receiving a length of insulated wire 1800. The length of insulated wire includes an electrically conductive inner core 1802 surrounded by an electrically insulating layer 1804. To aid in the explanation of the fabrication method, the insulated wire 1800 is described as having three segments, a first segment 1808, a second segment 1810, and a third segment 1812 disposed between the first segment 1808 and the second segment 1810. The length of insulating wire 1800 is wound on the spool 1526 of FIG. 15, with the third segment(s) 1812 of the length of insulated wire 1800 being disposed on the edges 1532, 1532 of the spool 1526. The third segment(s) 1812 of the length of insulated wire 1800 are covered by the masking members 1530, 1534 of the fixture.

Referring to FIG. 18b, an adhesion layer 1806 is deposited on the electrically insulating layer 1804 of the first segment 1808 of the electrically insulating layer 1804 and on the second segment 1810 of the electrically insulating layer 1804. The masking members 1530, 1534 of the fixture prevent deposition of the adhesion layer 1806 on the third segment 1812 of the electrically insulating layer 1804. In general, the adhesion layer serves to facilitate adhesion of an electroplated material to the insulated wire (as is described in detail below).

The masking members 1530 and 1534 are removed and replaced with the second set of masking members 1730, 1734 of FIG. 17. Additionally, the plating contact wire 1731 of FIG. 17 is inserted into the spool of the fixture 1526, making contact with the seed metal. The non-conductive clamps 1733 FIG. 17 ensure that the seed metal makes contact with the plating current source wire.

Referring to FIG. 18c, after deposition of the adhesion layer 1806, an electrically conductive shield layer 1816 is deposited on the first segment 1808 and the second segment 1810 (but not the third segment 1812, due to the presence of the masking members 1530, 1534).

Referring to FIG. 18d, after deposition of the electrically conductive shield layer 1816, the second set of masking members 1730, 1734 are removed and the electrically insulating layer 1804 of the insulated wire 1800 is removed from the third segment 1812, exposing the electrically conductive core 1802 in the third segment 1812. In some examples, the electrically insulating layer 1804 is removed using a laser cutting/etching process.

Referring to FIG. 18e, the electrically conductive core 1802 in the third segment 1812 is bisected (e.g., using a wire cutter or a blade), creating a first length of micro-coaxial wire 1818 with a first exposed section 1820 of electrically conductive core 1802 and a second length of micro-coaxial wire 1822 with a second exposed section 1824 of electrically conductive core 1802. In general, bisection of the third segment 1812 can occur either with the wire on the spool 1526 or with the wire off of the spool 1526.

In general, the procedure above can be used to generate a number of micro-coaxial wires, all with the same length, from a length of insulated wire. The length of the micro-coaxial wires generated by the fabrication procedure can be specified to meet the needs of a given application.

### 2.3.3 MEMS Based Fabrication

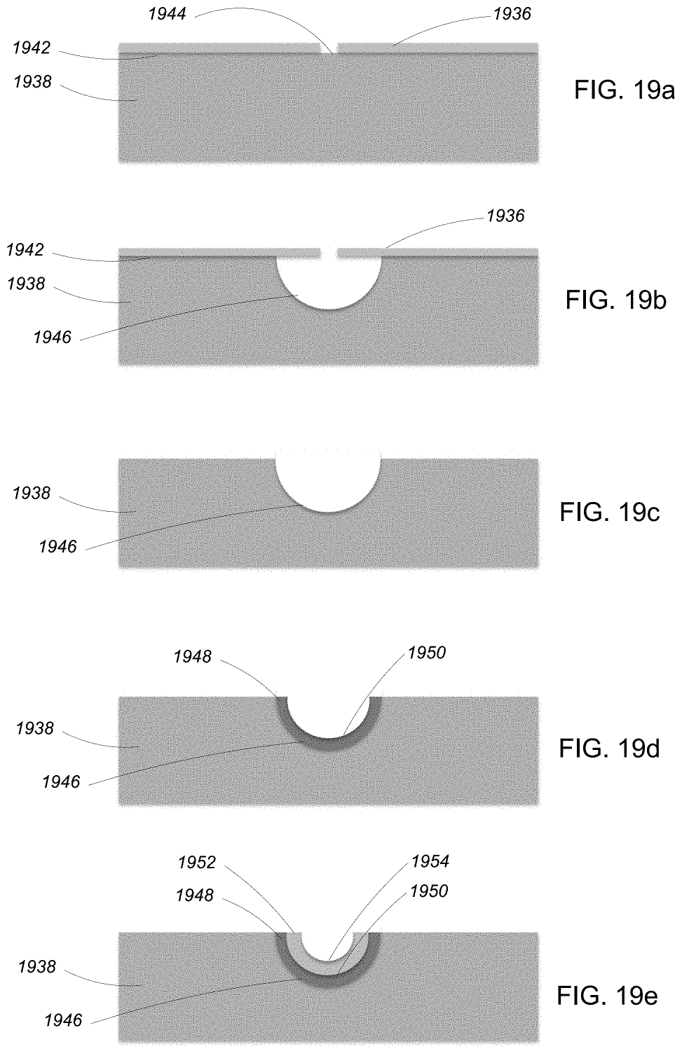

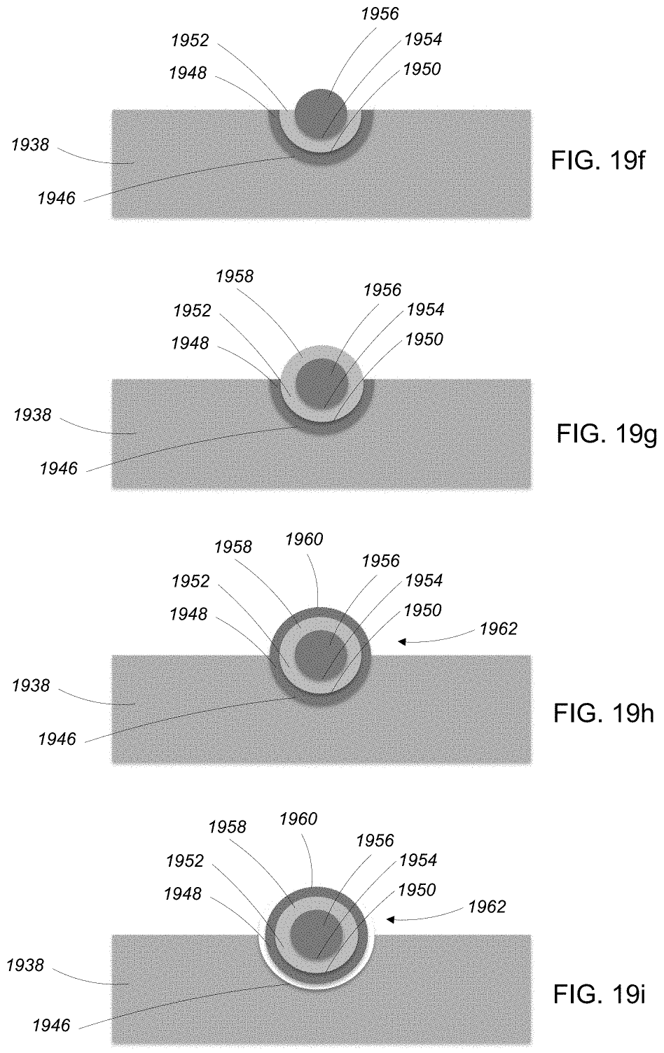

Referring to FIGS. 19a-19i, in some examples, micro-coaxial wires are fabricated using MEMS techniques.

Referring to FIG. 19a, in a first step, a masking layer 1936 (e.g., a polysilicon layer) is deposited on a substrate 1938 (e.g., a fused silica wafer) in a masking pattern 1940. In general, the masking pattern 1940 causes a first portion 1942 of the substrate 1938 to be covered by the masking layer 1936 and a second portion 1944 of the substrate 1939 to remain uncovered by the masking layer 1936. In the example of FIG. 19a, the masking pattern is simple (i.e., the second portion 1944 of the substrate that remains uncovered is a straight line extending into/out of the page). However, more complex masking patterns are likely to be used.

Referring to FIG. 19b, an etching procedure (e.g., a hydrofluoric acid etching procedure) is performed to remove material from the substrate 1938 in the area of the second portion 1944. In some examples, the material is removed such that a semicircular first cavity 1946 is formed in the substrate 1938.

Referring to FIG. 19c, after the etching procedure is performed, the masking layer 1936 is removed (e.g., using a polysilicon stripping procedure), exposing the substrate 1938.

Referring to FIG. 19d, a seed layer is deposited in the first cavity 1946 and a first part of a conductive shield layer 1948 (e.g., a copper layer) is deposited (e.g., electroplated or electroless plated) on the seed layer such that the first part of the conductive shield layer 1948 lines the first cavity 1946. A second cavity 1950 is formed by the first part of the conductive shield layer 1948.

Referring to FIG. 19e, a first part of an electrically insulating layer 1952 is deposited (e.g. by spraying photo-definable polyimide material) in the second cavity 1950 such that the first part of the electrically insulating layer 1952 lines the second cavity 1950. A third cavity 1954 is formed by the first part of the electrically insulating layer 1952.

Referring to FIG. 19f, a seed layer is deposited in the third cavity 1954 and an electrically conductive core 1956 (e.g., a copper or gold flashed copper core) is deposited on the seed layer in the third cavity 1954.

Referring to FIG. 19g, a second part of the electrically insulating layer 1958 is deposited (e.g., by spraying photo-definable polyimide material) on the electrically conductive core 1956 such that the first part of the electrically insulating layer 1952 and the second part of the electrically insulating layer 1958 encase the electrically conductive core 1956.

Referring to FIG. 19h, a seed layer is deposited on the second part of the electrically insulating layer 1958 and a second part of the conductive shield layer 1960 (e.g., a copper layer) is deposited (e.g. electroplated or electroless plated) on the seed layer such that the first part of the electrically conductive shield layer 1948 and the second part of the electrically conductive shield layer 1960 encase the electrically insulating layer. In FIG. 19h, the micro-coaxial wire 1962 is formed, but is still attached to the substrate 1938.

Referring to FIG. 19i, a glass etching procedure (e.g. a hydrofluoric acid etching procedure) is performed to release the micro-coaxial wire 1962 from the first cavity 1946.

### 2.4 Miscellaneous Micro-Coaxial Wire Features

In some examples, the electrically conductive materials and the electrically insulating materials are chosen to ensure that the two material types are compatible. For example, Ti is chosen as an adhesion layer because it sticks well to polymers, such as polyimide, polyurethane and polyester-imide. Additionally, aluminum doped silicon adheres better to Cu than does pure silica. A Cu/Mn alloy can be deposited using CVD onto a polymer or ceramic material and provides both good adhesion and a good electroplating foundation. CVD can be used to create a signal micro-coaxial wire with 50Ω impedance on commercially available 10 μm core wires. CVD can also apply ultra thin (<1 μm) dielectrics to a core wire with a diameter between 10 μm and 500 μm to create ultra-low impedance micro-coaxial wires.

In some examples, to fabricate micro-coaxial wire for signal distribution (e.g., 30Ω-70Ω) with less than 25 μm outer diameter, CVD is used to deposit a polymer dielectric on an electro-spun nanofiber. In some examples, to fabricate a micro-coaxial wire for power distribution (e.g., less than 10Ω), CVD is used to deposit a ceramic dielectric on an electro-spun nanofiber.

In some examples, at least some steps of certain micro-coaxial fabrication methods can be performed in a reel-to-reel system. For example, wires are configured to travel from a first reel, through various coating/electroplating stages, and onto a second reel.

In some examples the electrically conductive shields are formed from a solder-based material. In some examples, the electrically conductive shields and/or the electrically conductive inner cores are formed from low atomic weight materials (e.g., aluminum or beryllium) and the electrically insulating layer is formed from a low density polymer. In some examples, Kevlar insulation or threads can be used to strengthen the micro-coaxial wires.

In some examples, all three sections of the insulated wire are plated with a thermally removable shield layer (e.g., a solder based shield), and the portion of the thermally removable shield layer on the third segment of the insulated wire is thermally removed during the fabrication process.

In some examples, the electrically conductive inner core is formed from one or more of a copper material, a gold flashed copper material, a gold material, a silver material, a tin material, a nickel material, or an alloy of one or more of a copper material, a gold material, a silver material, a tin material, a nickel material.

In some examples, the electrically conductive shield layer is formed from one or more of a copper material, a gold material, a silver material, a tin material, a nickel material, or an alloy of one or more of a copper material, a gold material, a silver material, a tin material, a nickel material.

In some examples, the electrically conductive shield layer is deposited by drawing the insulated wire through a suspension of metallic particles in a polymeric material. The metallic particles may include one or more of metallic flakes, metallic nanoparticles, and metallic microparticles. The metallic particles may be formed from one or more of a copper material, a gold material, a silver material, a tin material, a nickel material, or an alloy of one or more of a copper material, a gold material, a silver material, a tin material, a nickel material.

In some examples, the electrically conductive shield layer is deposited by vapor depositing the shield layer.

In some examples, the adhesion layer includes an organic adhesion promoter.

Very generally, micro-coaxial wires include a core (e.g., a copper or gold flashed copper core), a dielectric layer (e.g., a polymer, parylene, or HfO2 dielectric) disposed on the core, and a shield layer (e.g., a copper or gold shield) disposed on the dielectric layer. Micro-coaxial wires with different configurations are used to distribute signals and power. Furthermore, micro-coaxial wires are dimensioned based on the integration strategy in which they are deployed (e.g., bare die integration or multi-chip package integration).

At the time of writing, a commercial lower limit on the diameter of the core is 10 μm for power distribution wires and 25 μm for signal distribution wires. A reasonable lower limit for the diameter of the core is 5μm. It is possible to fabricate a core smaller than 5 μm, but skin depth, current capacity, operational frequency and signal transmission distance must be considered for the given application. A 5 μm Cu core is sufficient for transmitting a single for 0.5 to 11 mm with less than 10/mm resistive loss. For power delivery, a 5 μm Cu core would deliver a maximum of 6.8 mW/cm and have a fusing current of 28 mA.

Some coaxial wires used for signal distribution, have a maximum of 5% power attenuation across a 10 mm trace (e.g., 1-Ohm per mm). Some specific designs may have tighter or looser attenuation requirements. In some examples, for coaxial wires used both for power distribution and signal distribution, the cross-sectional core conductance is designed to be approximately equal to or greater than the shield conductance. In some examples, the resistance of the shield is greater than or equal to the resistance of the core. If the core and the shield are the same material (e.g., Both Cu or both Au), then the cross section area of the two are matched. If they are different materials, the minimum shield area scales with the conductivity ratio (or resistivity ratio, which is the inverse of the conductivity ratio). In some examples, no core radius or shield thickness is smaller than the skin depth.

One way of manufacturing micro-coaxial wires includes starting with a commercial insulated wire, sputtering a seed layer onto the commercial insulated wire, and then electroplating a shield onto the seed layer. Another way of manufacturing micro-coaxial wires includes starting with a commercial insulated wire, electroless plating a seed layer onto the commercial insulated wire, and then electroplating or immersion plating a shield layer onto the seed layer. In some examples, a length of wire produced by the manufacturing processes and spooled is greater than 15 feet. In some examples, a length of wire produced by the manufacturing processes and spooled is at least approximately 500 feet and is as much as 10,000 feet.

It is noted that, while the examples described herein refer to the core wire as being a copper core wire, some examples use a copper core wire that is flashed with gold—where the copper portion of the core wire provides structural strength and the gold flash enables de-wetting of the dielectric.

### 3 Tooling

In some examples, specialized tools are used to fabricate, handle, route, and attach the micro-coaxial wires.

### 3.1 Wire Handling/Stripping

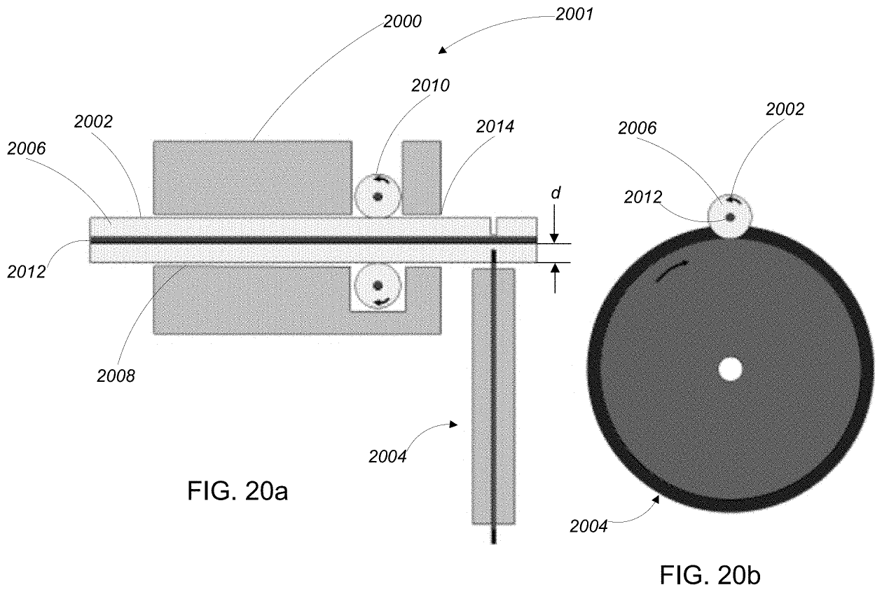

Referring to FIG. 20A and FIG. 20B, an apparatus 2001 for feeding and layer removal of coaxial wires includes a tubular feed mechanism 2000 for feeding and rotating a coaxial wire 2002 and a spinning cutting blade 2004 for cutting through one or more layers 2006 of the coaxial wire.

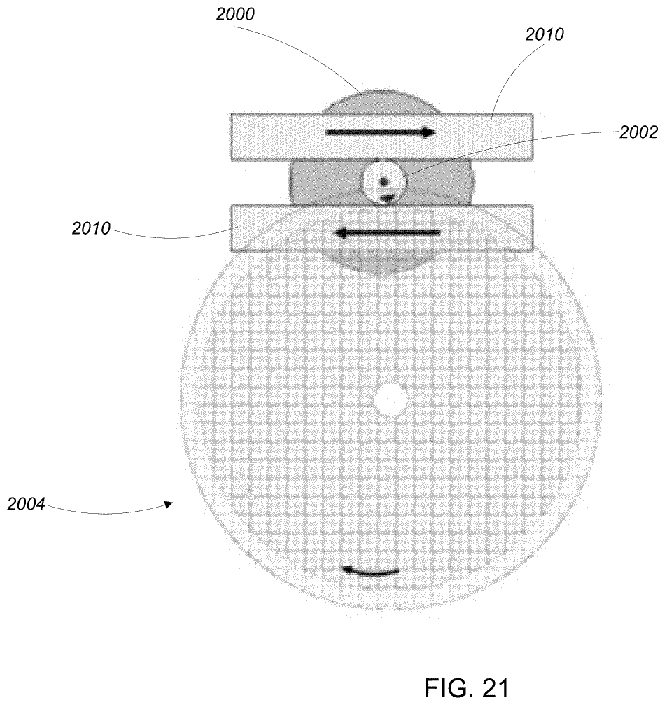

The tubular feed mechanism 2000 includes a tube 2008 and more rotating shafts 2010 disposed adjacent to the tube 2008 for engaging an outer surface of the coaxial wire 2002. The rotation of the shafts 2010 feeds (i.e., pushes or pulls) the coaxial wire 2002 through the tube 2008. In some examples, the shafts 2010 also move linearly along their own axes see (e.g., FIG. 21), causing rotation of the coaxial wire about its core 2012. In general, the shafts 2010 are capable of rotating the wire at least 360 degrees about its core 2012.

The spinning cutting blade 2004 is disposed adjacent to and just outside an opening 2014 of the tube 2008, and is configured to make an incision about the entire circumference of the coaxial wire 2002 to a predetermined depth, d as the wire 2002 rotates about its core 2012.

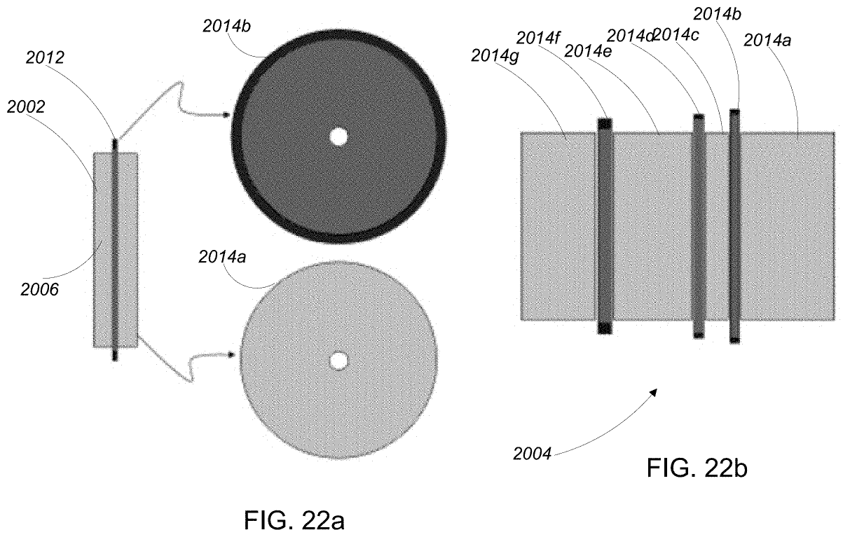

Referring to FIG. 22a and FIG. 22b, in some examples, to precisely cut insulation and shielding to a required depth, the spinning cutting blade 2004 is comprised of multiple stacked disks 2014a-2014g. One or more of the disks (e.g., 2014b, 2014d, 2014f) are cutting blades while others of the disks are stops (e.g., 2014a, 2014c, 2014e, 2014g). The disks are stacked so that the cutting disks sit between two stop disks. By setting a diameter of the cutting disks to be larger than the stop disks, the penetration (i.e., depth) of the cut is governed by the difference in radii between the particular cutting disk and stop disks. The disk diameters are machined to high precision to ensure that the cut depth of each cutting disk is precise.

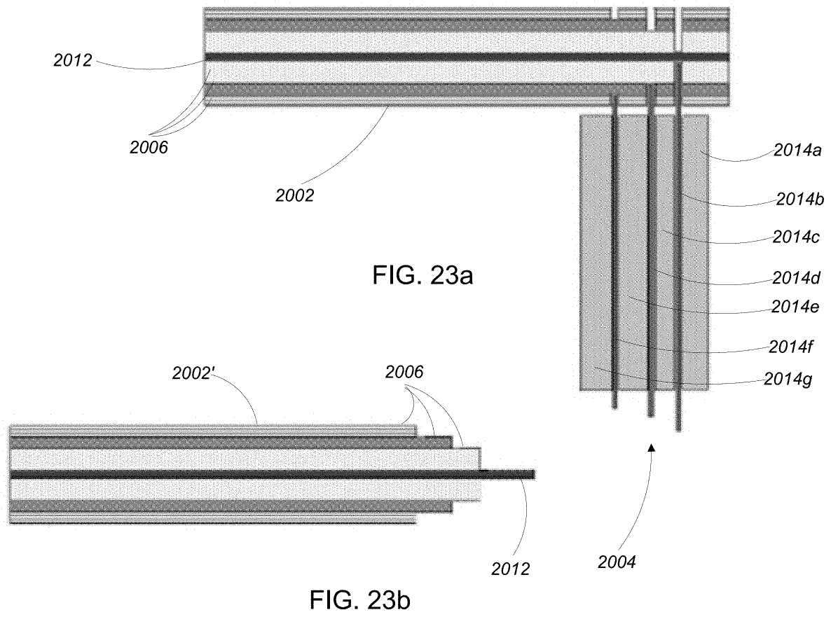

Referring to FIG. 23a and FIG. 23b, a coaxial wire 2002 is shown engaged with the spinning cutting blade 2004, which has cut through a number of layers 2006 of the coaxial wire 2002. The result of cutting and removal of the layers 2006 from the coaxial wire 2002 is shown as a stripped coaxial wire 2002′.

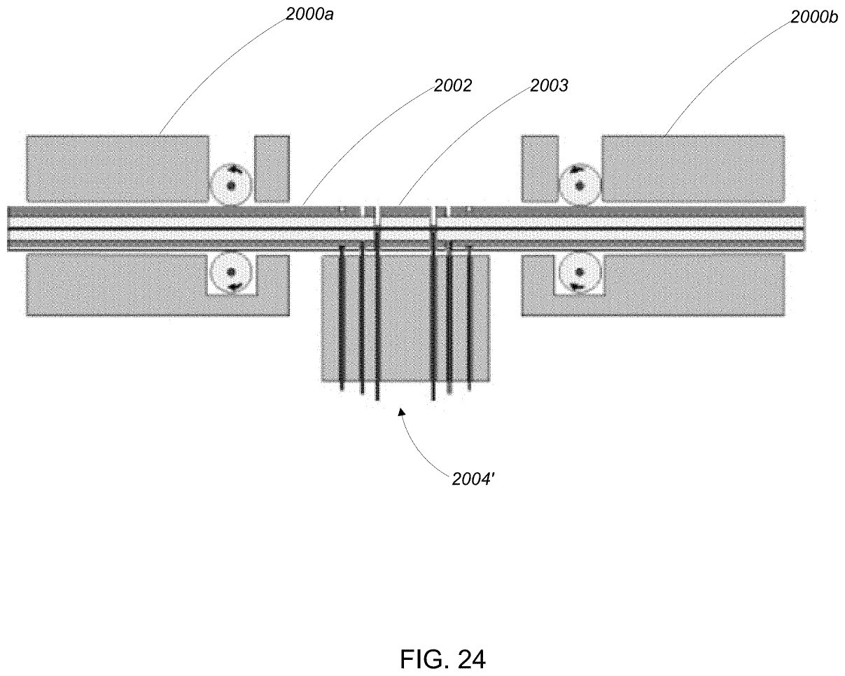

Multiple continuous feed configurations are possible using the above-described components. For example, referring to FIG. 24, two tubular feed mechanisms 2000a, 2000b can be used along with a compound spinning cutting blade 2004′ to remove layers of material from a midsection 2003 of a coaxial wire 2002 (rather than from an end section).

In an alternate embodiment, the spinning cutting blade 2004 can be fabricated as a cylindrical drum having uniform diameter with a cutting wire wrapped around the drum and adhered to the drum. In this configuration, the cutting wire diameter defines the cutting depth while the drum it is mounted to provides a cut-stop.

In some examples, the above-described apparatus is implemented as a modification to a conventional wire bonder. In some examples, the above-described tool is configured to operate on 1 mm diameter micro-coaxial wires.

### 3.2 Continuous Feed Attachment Tool

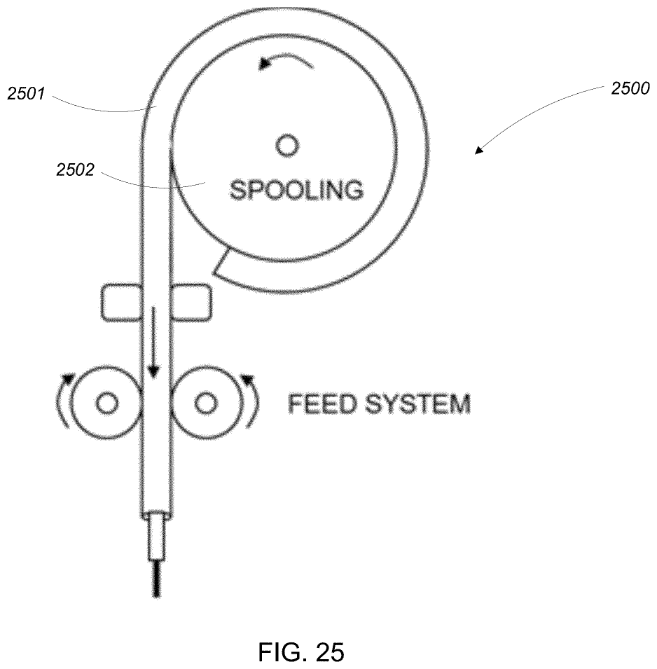

Referring to FIG. 25, in some examples an attachment tool 2500 continuously feeds micro-coaxial wire 2501 from a spool 2502 and attaches the micro-coaxial wire 2501 according to one or more of the attachment strategies described above.

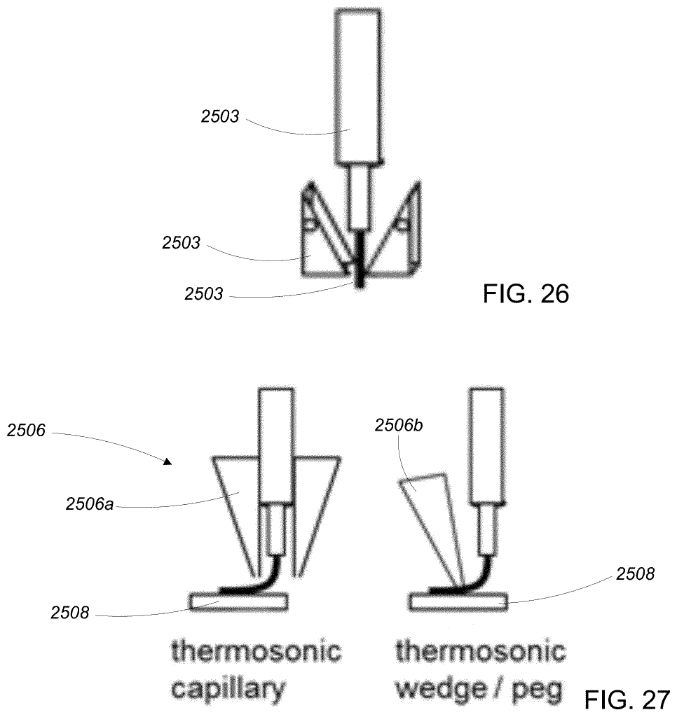

Referring to FIG. 26, in some examples, the attachment tool 2500 includes a wire stripper 2503 for stripping the micro-coaxial wire to expose the conductive inner core 2504. Referring to FIG. 27, in some examples, the attachment tool 2500 includes a welding apparatus 2506 (e.g., a thermosonic capillary welding apparatus 2506a or a thermosonic wedge/peg welding apparatus 2506b) for attaching the conductive inner core 2504 to a connection point 2508.

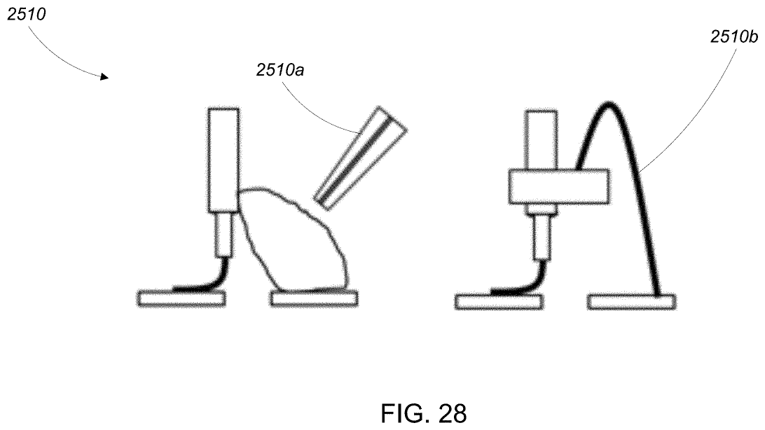

Referring to FIG. 28, in some examples, the attachment tool 2500 includes a shield attachment apparatus 2510 (e.g., a conductive material dispenser 2010a or a jumper wire attachment apparatus 2010b) for connecting the conductive shield of the micro-coaxial wire to ground (or another connection point).

In some examples, the attachment tool is configured to pick and place of pre-made micro-coaxial wires for wire attachment.

### 3.3 Wire Routing

In some examples, specialized wire routing algorithms are used to route the micro-coaxial wires. For example, the wire routing algorithms are configured to ensure that connection points are not obscured and inaccessible. The wire routing algorithms may plan non-straight line routes for the micro-coaxial wires to follow. In some examples, the wire routing algorithms may wrap the micro-coaxial wires around posts in the circuit to facilitate certain non-straight line routes.

In some examples, the routing algorithms may generate three-dimensional wiring maps.

### 4 Micro-Coaxial Wire Dimensions

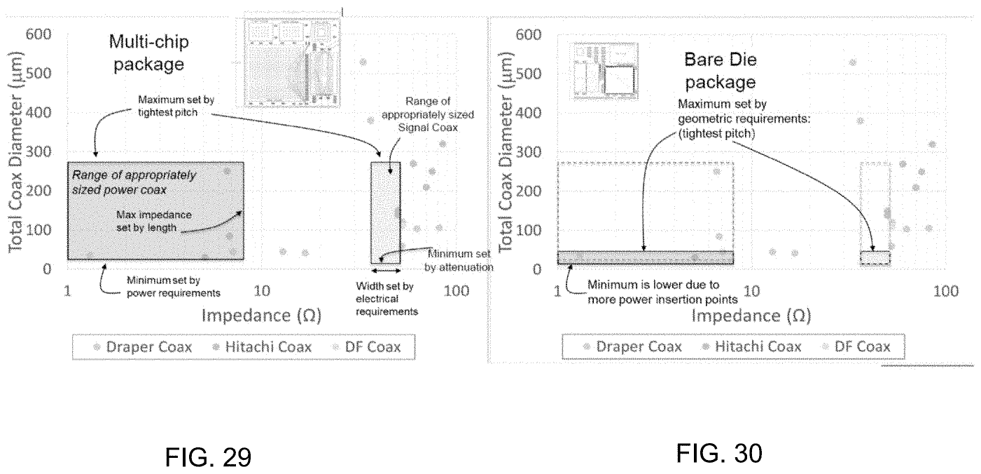

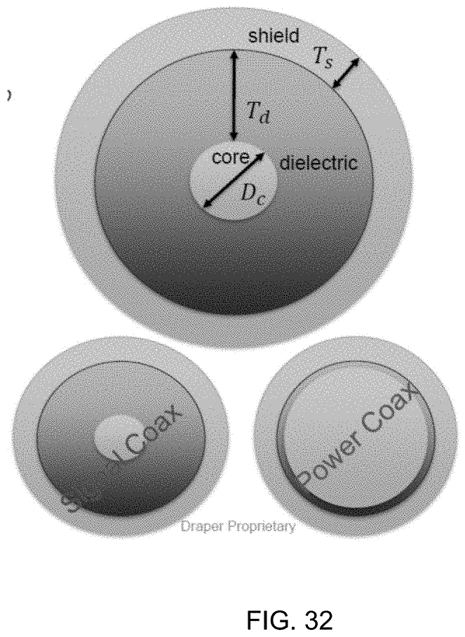

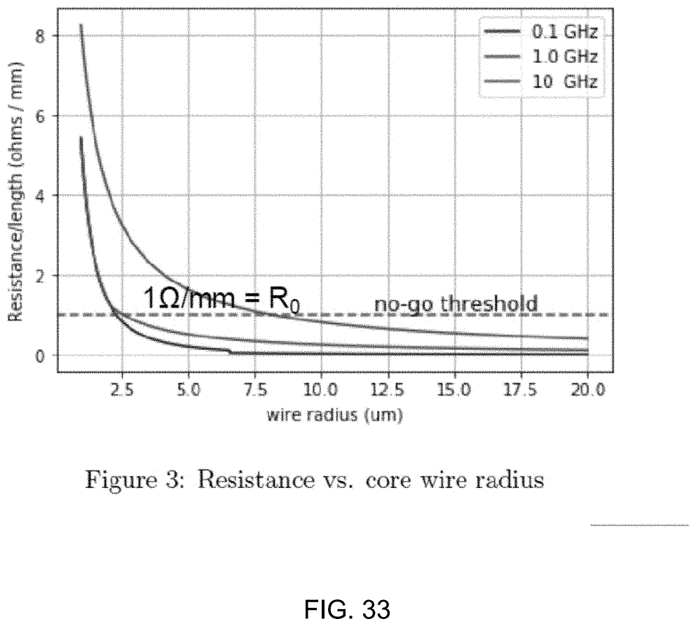

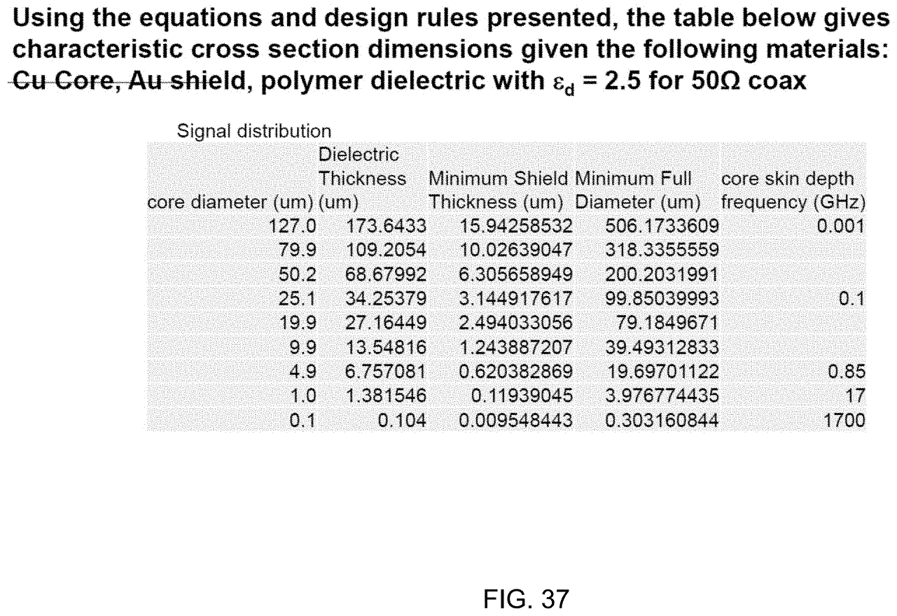

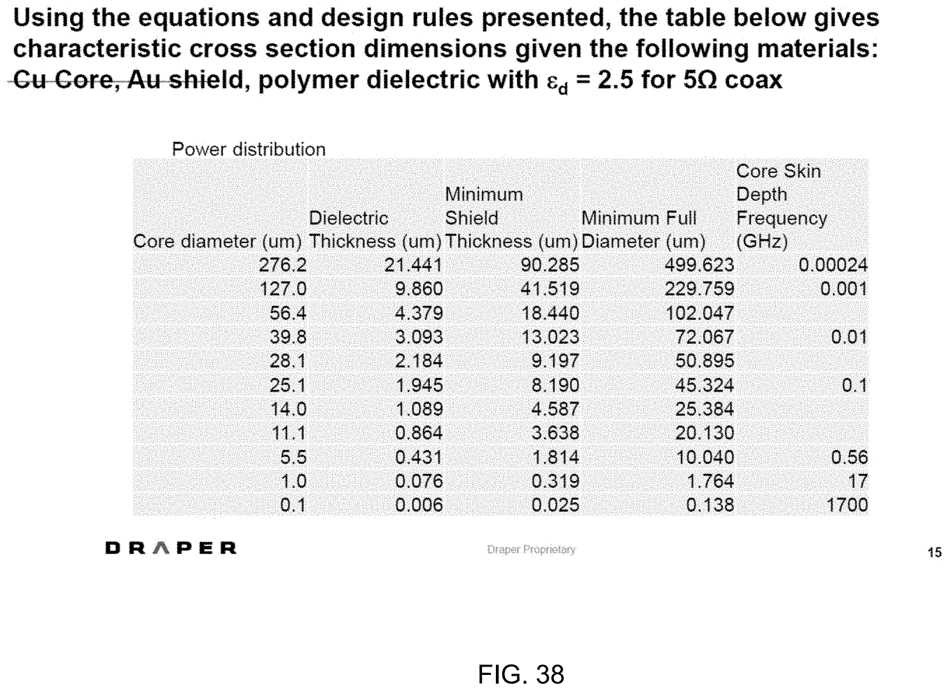

Referring to FIGS. 29-43, a number of considerations and equations for defining the dimensions of micro-coaxial wires are set forth. One general goal of micro-coaxial wires is to replace solid metal bond wires that are conventionally used in wire bonding systems for die scale integration. One example of conventional gold solid metal bond wires has a wire diameter in a range of 0.7 mil to 3.0 mil (18 μm-76 μm) and a pitch down to 35 μm. An example of a conventional aluminum solid metal bond wire has a wire diameter in a range of 0.8 mil to 2.0 mil (20 μm-52 μm) and a pitch down to 60 μm. An example of copper solid metal bond wires has a wire diameter in a range of 0.7 mil to 1.0 mil (18 μm-25 μm) and pitch down to 35 μm. Current research efforts are attempting to develop gold solid metal bond wires with a 10 μm diameter and copper solid metal bond wires with a diameter of 12.5 μm, both on a 20 μm pitch.

Another general use of micro-coaxial wires is in package scale integration. For example, micro-coaxial wires can be used to integrate a ball grid array with a pitch that ranges from 0.5 mm to 1.0 mm. When integrating a packaged chip using wire bonding techniques, the wire bonding head is approximately twice the diameter of the wire, and therefore the maximum diameter of a wire must be about ½ of the maximum pitch.

In some examples, a suitable micro-coaxial wire has an outer diameter in a range of 0.14 μm to 500 μm.

Referring to FIG. 29, wire range dimensions for a particular example of a multi-chip package integration are shown in a scatter plot. In the multi-chip package, the range of appropriately sized micro-coaxial wires for power distribution is constrained by the length of the wire (which constrains the maximum impedance), the tightest pitch for the integration (which constrains the maximum outer diameter of the wire), and the power requirements for the integration (which constrains the minimum outer diameter of the wire). In this particular example, the outer diameter of micro-coaxial wires for power distribution is constrained to a range of 20 μm to 280 μm and the impedance is constrained to a range of 152 to 8Ω.

The range of appropriately sized micro-coaxial wires for signal distribution is constrained by the electrical requirements for the integration (which constrain the impedance range) and the tightest pitch for the integration (which constrains the maximum outer diameter for the micro-coaxial wire). In this particular example, the outer diameter of the micro-coaxial wires for signal distribution is constrained to a range of 20 μm to 280 μm and the impedance is constrained to a range of 30Ω to 60Ω.

Referring to FIG. 30, wire range dimensions for a particular example of bare die package integration are shown in a scatter plot. In the bare die package, the range of appropriately sized micro-coaxial wires for power and signal distribution have the same constraints, but the ranges of appropriately sized wires are smaller due to the tighter geometric requirements (e.g., pitch) and an increased number of power insertion points. In the particular example in FIG. 30, the outer diameter of micro-coaxial wires for power distribution is constrained to a range of 15 μm to 250 μm and the impedance is constrained to a range of 152 to 8Ω. The outer diameter of the micro-coaxial wires for signal distribution is constrained to a range of 15 μm to 25 μm and the impedance is constrained to a range of 3052 to 60Ω.

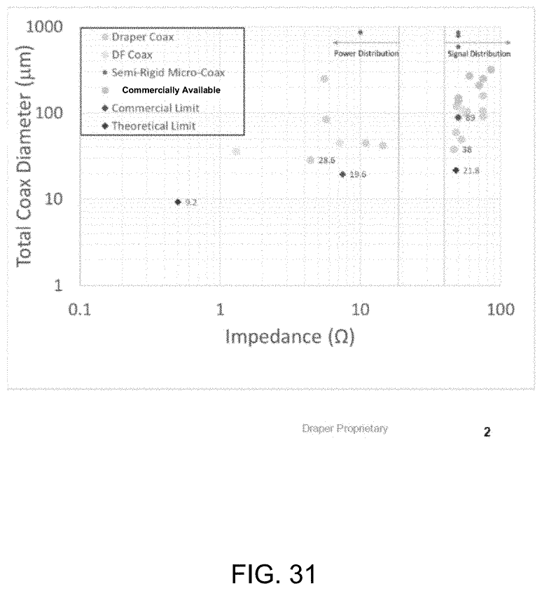

Referring to FIG. 31, another scatter plot shows outer diameter vs. impedance for the micro-coaxial wires described herein, as well as a number of other types of coaxial wires and commercial and theoretical limits.

The micro-coaxial wires described herein and characterized by the scatter plot have a copper or gold flashed copper core, a solid polymer dielectric, a copper or gold shield, and no jacket.

Another type of coaxial wire, referred to as “DF coax” and characterized by the scatter plot have a solid gold core wire, a solid Parylene C dielectric or HFO2 dielectric, a solid gold shield, and no outer jacket.

A semi-rigid micro-coaxial wire characterized by the scatter plot has a copper core, a solid polymer dielectric, a copper or gold shield, and no jacket. The semi-rigid coaxial wire is offered in a variety of impedance values including 10Ω, 17Ω, 25Ω, 50Ω, 75Ω, and 93Ω.

A smallest commercially available wire characterized by the scatter plot has a solid or stranded core, a foam and tape wrapped dielectric, and a stranded shield. This configuration is more flexible than the semi-rigid micro-coaxial wire but is also lossier.

A commercial limit characterized by the scatter plot has power distribution wires based on a 10 μm copper core (the smallest commercially available thin-film insulated wire) and signal distribution wires based on a 25 μm copper core (the smallest commercially available thick-film insulated wire).

A theoretical limit characterized by the scatter plot is based on a 5 μm core, which can be fabricated by planting on an electrospun polymer nano-wire and 1 GHz minimum operation frequency (which is skin-depth dependent).

### 4.1 Design Rules

Referring to FIG. 33, the above-described wire dimensions are determined based on design rules which, given a desired impedance and core wire radius (rc), can be used to derive dielectric thickness (Td) and shield thickness (Ts).

Very generally, for a coaxial wire, the DC resistance, R_{DC} is expressed as the sum of the core resistance, R_{core} and the shield resistance, R_{shield}, both normalized to wire length:

$$\frac{R}{l} = \frac{{R}_{core}}{l} + \frac{{R}_{shield}}{l} .$$

At DC, R_{core} and R_{shield}, are functions of wire geometry, so the total resistance at DC, R_{DC} per unit length in Q/m is:

$$\frac{{R}_{DC}}{l} = \frac{{ρ}_{c}}{π {r}_{c}^{2}} + \frac{{ρ}_{s}}{π [ {( {r}_{c} + {t}_{d} + {t}_{s} )}^{2} - {( {r}_{c} + {t}_{d} )}^{2} ]} .$$

To determine the shield thickness, the dielectric thickness must first be determined. To do so, the inductance, L per unit length is determined as:

$$\frac{L}{l} = \frac{{μ}_{0}}{2 π} ln ( \frac{{r}_{c} + {t}_{d}}{{r}_{c}} ) .$$

Using the above wire inductance equation, the necessary dielectric thickness for a micro-coaxial wire can be determined for a desired wire inductance and core wire radius.

The characteristic impedance, Z₀ for a micro-coaxial wire can be expressed as:

$${Z}_{0} = \sqrt{\frac{R + j ω L}{G + j ω {C}^{′}}}$$

(where R is the total resistance per unit length of wire, L is the total inductance per unit length of wire, C is the total capacitance per unit length, and G is the conductance per unit length) which simplifies to:

$${Z}_{0} = \sqrt{\frac{L}{{C}^{′}}}$$

for highly resistive dielectrics and highly conductive metals.

Finally, the capacitance for unit length of micro-coaxial wire is expressed as:

$$\frac{C}{l} = \frac{2 {πɛ}_{0} {ɛ}_{r}}{ln ( \frac{{r}_{c} + {t}_{d}}{{r}_{c}} )}$$

In the equations above, l is the wire length, r_{c} is the core radius, t_{d} is the dielectric thickness, tₛ is the shield thickness, is the core resistivity, ρₛ is the shield resistivity, μ₀ is the magnetic permittivity in free space, μᵣ is the magnetic permittivity constant, ε₀ is the electric permittivity free space, and εᵣ is the dielectric constant.

### 4.1.1 Signal Distribution Wire Design Rules

For signal distribution wires, the goal is to minimize power attenuation (i.e., <5%) and be impedance matched to a load on the chip (30Ω-75Ω). For example, a 10 mm long interconnect should have a resistive loss ≤1 Ω/mm.

In general, a larger core diameter (Dc) is needed when a conductivity of the core wire material is low (i.e., resistive loss) and when an average wire length is long (i.e., resistive loss). In some examples, Dc≥5 μm for signals at >1 GHz with an average trace length of 10 mm.

The dielectric thickness (Td) is larger when the impedance is high and the dielectric constant is high. In general, the shield conductivity is ≥the core conductivity.

In one example, the resistance of the shield is assumed to be equal to the resistance of the core wire and the core radius (rc) is chosen to be as large as possible (to minimize resistance).

The core radius (r_{c}) is determined by the following equation:

$${r}_{c} \geq \sqrt{\frac{2}{{πσ}_{c} {R}_{0}}} .$$

The dielectric thickness (T_{d}) is determined by the following equation:

$${T}_{d} = {r}_{c} ( {e}^{{Z}_{0} \sqrt{{ɛ}_{d}} / 60} - 1 ) .$$

The shield thickness (T) is determined by the following equation:

$${T}_{s} \geq \sqrt{{r}_{c}^{2} ( \frac{{σ}_{c}}{{σ}_{s}} ) + {( {r}_{c} + {T}_{d} )}^{2}} - ( {r}_{c} + {T}_{d} ) .$$

In the equations above, ε_{d} is the dielectric constant, σ_{c} is the conductivity of the core wire, σₛ is the conductivity of the shield, and R₀ is the resistance per unit length.

### 4.1.2 Power Distribution Wire Design Rules

For power distribution wires, the goal is to ensure that the micro-coaxial wire interconnect impedance is less than or equal to an impedance tolerance for a multi-chip system (power distribution networks have a maximum tolerable system impedance defined by their components).

In general, a larger core diameter (Dr) is needed when the conductivity of the core material is low, the average wire length is long, there are higher current requirements, and/or the system impedance limit is small. In some example, Dc≥12 μm for the most power-hungry chips.

The dielectric thickness (T_{d}) is required to be small (e.g., less than 10% of the core diameter (D_{c})).

The conductivity of the shield layer should be greater than or equal to the conductivity of the core wire.

For a very basic power distribution network, the multi-chip system impedance (Z_{sys}) is defined by the following equation:

Z_{sys}=R_{sys}+jωL_{sys}.

For low frequency and/or low inductance Z_{sys}≈R_{sys}.

The core radius (r_{c}) is determined by the following equation:

$${r}_{c} \geq \sqrt{\frac{2 \overline{l}}{π N {σ}_{c} {Z}_{sys}}} .$$

In general, r_{c}≥12 μm.

The dielectric thickness (Td) is much less than the core radius and is approximated to zero (i.e., T_{d}<<r_{c}≈0).

The shield thickness (Ts) is determined by the following equation:

$${T}_{s} \geq {r}_{c} ( \sqrt{( \frac{{σ}_{c}}{{σ}_{s}} ) + 1} - 1 ) .$$

In the equations above, R_{sys} is the multi-chip system resistance, L_{sys} is the multi-chip system inductance, ω is the frequency in radians, l̅ is the mean trace length, N is the number of wires to power the chip, σ_{c} is the conductivity of the core wire, and σₛ is the conductivity of the shield.

### 4.1.3 Skin Depth Considerations

Referring to FIG. 33, as a general rule, no core radius or shield thickness is smaller than the skin depth. So, the design rules and equations set forth above should be checked against the skin depth, δ as follows:

$${T}_{d} , {r}_{c} \geq \sqrt{\frac{1}{π f σ μ}}$$

where f is the frequency in degrees, σ is the conductivity, and μ is the magnetic permeability.

As is shown in the graph of FIG. 33, the resistance per unit length (R₀) should remain below 1 Ω/mm.

### 4.1.4 Miscellaneous Design Considerations

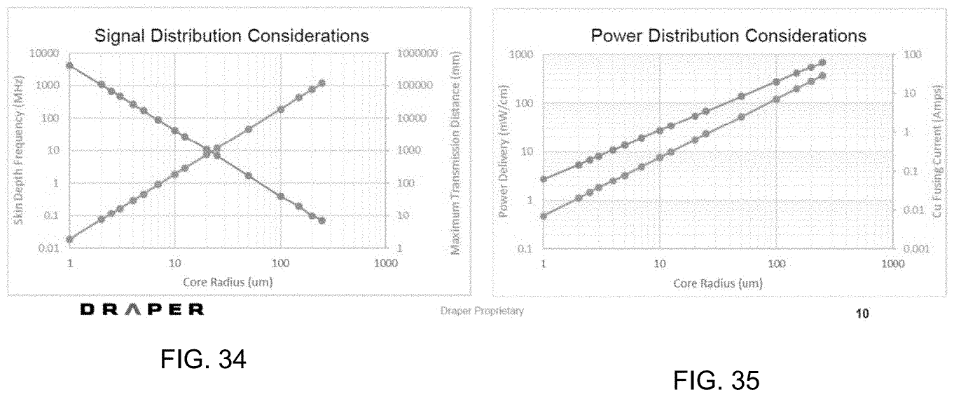

Referring to FIG. 34, a graph of core wire radius vs. skin depth frequency and maximum transmission distance shows that transmission distance and frequency play a critical role in signal distribution. With a small core wire diameter, resistive losses become high over long transmission distances. A small core wire diameter increases the minimum operational frequency due to skin depth.

Referring to FIG. 35, a graph of core wire radius vs. power delivery and copper fusing current shows that fusing current and power requirements play critical roles in power distribution. Ling distances between power supply and chip I/O requires larger core wire diameters. With smaller core wire diameters, current capacity is limited.

### 4.2 Wire Configurations

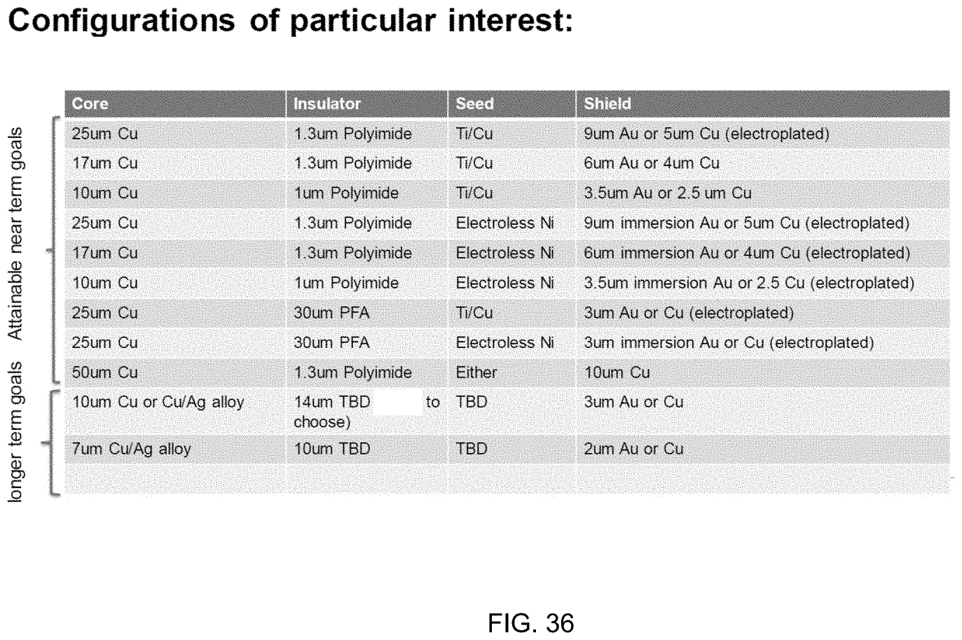

Referring to FIGS. 36-38, a number of exemplary wire configurations that conform to the above-described design rules are illustrated.

### 5 Reel-to-Reel Wire Fabrication

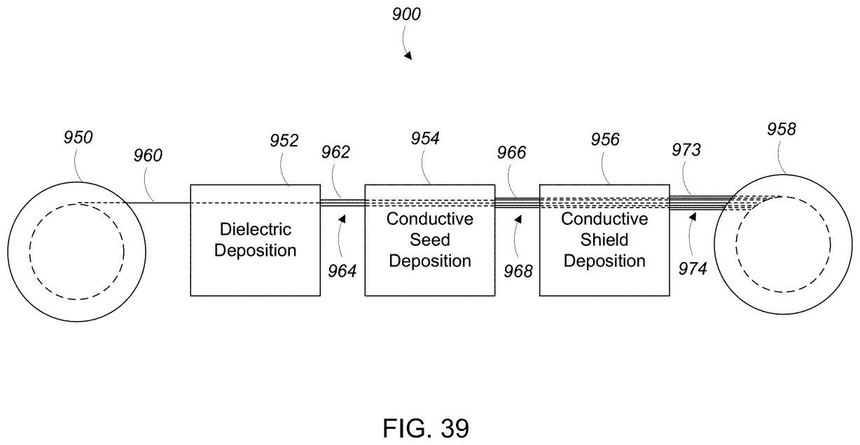

Referring to FIG. 39, a system 900 for reel-to-reel fabrication of micro-coaxial wires is able to fabricate micro-coaxial wire segments with lengths in the hundreds of feet. The system 900 includes a spool of drawn copper or gold flashed copper 950, a dielectric deposition system 952, a conductive seed deposition system 954, a conductive shield deposition system 956, and a spool of fabricated wire 958.

Before describing the fabrication system in any more detail, it is noted that, while FIG. 39 shows and end-to-end fabrication system where only the finished micro-coaxial wire is spooled, there may be system configurations where the wire is re-spooled at intermediate stages in the fabrication process. Indeed, some or all of the steps in the fabrication procedure may draw the wire from a spool, operate on the wire, and then re-spool the wire.

With that said, the reel-to-reel fabrication process performed by the system 900 begins by de-spooling a drawn copper or gold flashed copper wire 960 from the spool of drawn copper or gold flashed copper wire 950. In some examples, the drawn copper or gold flashed copper wire 950 is a cooper wire that has been drawn to a specific dimension commercially. For example, when fabricating a micro-coaxial wire for power distribution, the copper or gold flashed copper wire 950 has a diameter of 10 μm, 20 μm, or 25 μm. When fabricating a micro-coaxial wire for signal distribution, the copper or gold flashed copper wire 950 has a diameter of, for example, 25 μm.

The copper wire is provided to the dielectric deposition system 952 which deposits a dielectric layer 962 on the copper or gold Hashed copper wire 950. In some examples, for power distribution micro-coaxial wires, the dielectric layer 962 is a Polyimide-ML layer that is deposited using an enameling process. For signal distribution micro-coaxial wires, the dielectric layer 962 is a PerHuoroalkoxy polymer layer this is deposited using a co-extmsion process.

In other examples, to achieve micro-coaxial wires with a diameter less than 90 μm and an impedance of 50Q-70Q, the dielectric deposition system 952 deposits a Parylene N coating on copper wires having a diameter in the range of 10 μm-18 μm In such examples, a chemical vapor deposition (CVD) process is used by the dielectric deposition system 952 to deposit the Parylene N dielectric layer. In yet other examples, the dielectric deposition system 952 uses an electrospray or low-tension extrusion process to deposit the dielectric layer 962.

The wire with the dielectric layer deposited 964 is provided to the conductive seed deposition system 954 which deposits a conductive seed layer 966 onto the dielectric layer 962. In general, the seed layer 966 is deposited to enable subsequent deposition of the conductive shield layer (described below). In some examples, the seed layer 966 includes a 100 nm thick layer of titanium and a 400 nm thick layer of copper. In some examples the seed layer 996 includes a layer of titanium and a layer of gold. In some examples, the seed layer 996 includes silver.

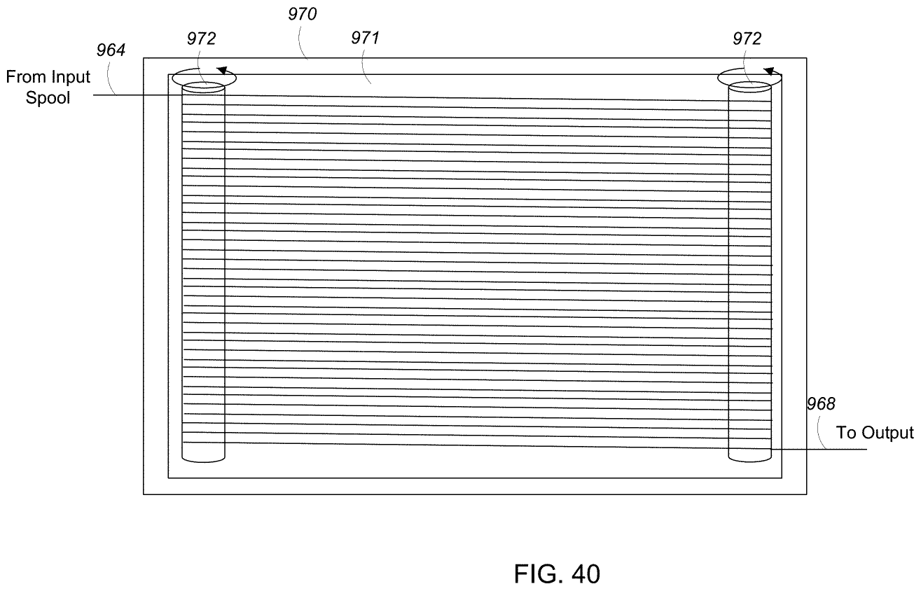

Referring to FIG. 40, the conductive see deposition system 954 uses a sputtering-based process to deposit the seed layer 966. A fixture 970 holds a long section of wire 964 in a sputtering chamber and slowly moves the wire to ensure that the seed layer 966 is deposited on all parts of the wire. In particular, the fixture 970 includes a chamber 971 with two threaded rotatable cylinders 972 disposed opposite one another. The wire 964 is wound between the cylinders 972 with the wire 964 resting in the threads of the cylinders 927 (maintaining a separation between sections of the wire). During the sputtering process, the cylinders 972 are periodically rotated (e.g., ¼ turn), drawing the wire 964 from the input spool, moving the wire 964 through the chamber 971 and exposing parts of the wire 964 that were in contact with the cylinders (and therefore not receiving seed layer) to the sputtering process, ensuring that they receive the seed layer. Finally, the wire with the seed layer deposited thereon 968 is output.

Using the fixture 970, wire segments greater than 24 inches (and up to 750 ft) can be efficiently coated with a seed layer in a reel-to-reel fashion. In some examples, 300 ft of 18 μm diameter wire can be coated and spooled in about two hours.

Referring again to FIG. 39, in some examples, a sputtering power used in the conductive seed deposition system 954 is controlled to reduce roughness and oxidation of the copper in the seed layer.

In another example, the conductive seed deposition system 954 uses a electroless nickel plating process to deposit the seed layer 966 without needing to sputter or evaporate material onto the dielectric layer 962. A copper plating shield or an immersion gold shield can be deposited onto the nickel seed layer 966.

The wire with the seed layer deposited thereon 968 is provided to the conductive shield deposition system 956 which deposits a conductive shield layer 973 onto the seed layer 966, resulting in the final micro-coaxial wire 974. In some examples, the conductive shield deposition system 956 uses a reel-to-reel copper electroplating procedure. The final micro-coaxial wire 974 is wound onto the spool of fabricated wire 958.

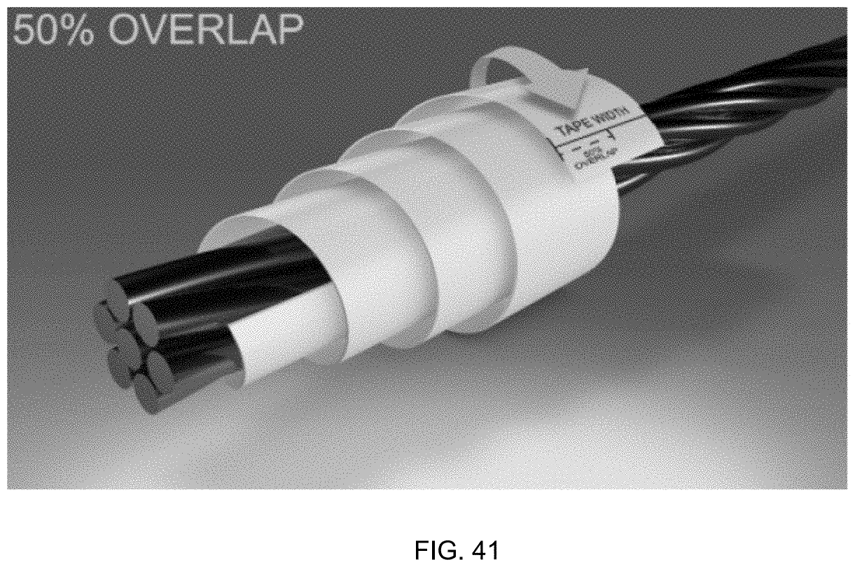

It is noted that, in some examples, the conductive seed deposition system 954 is not used and no seed layer is applied to the wire. For example, referring to FIG. 41, a foil wrap procedure can be used to deposit the shield layer 973, obviating the need for vacuum deposition equipment.

The approaches described above can be used to improve or modify the approaches that are described in the following pending patent applications, each of which is incorporated herein by reference: U.S. Ser. No. 15/592,694, filed May 11, 2017, titled “WIRING SYSTEM”; U.S. Ser. No. 62/545,561, filed Aug. 15, 2017, titled “ELECTRIC-FLAME-OFF STRIPPED MICRO COAXIAL WIRE ENDS”; U.S. Ser. No. 62/545,546, filed Aug. 15, 2017, titled “WIRE WITH COMPOSITE SHIELD.”

It is to be understood that the foregoing description is intended to illustrate and not to limit the scope of the invention, which is defined by the scope of the appended claims. Other embodiments are within the scope of the following claims.

1. A manufacture including a coaxial wire with a 50-Ohm impedance and an outer diameter in a range of 0.2 μm-550 μm, the coaxial wire having a conductive core with an outer diameter in a range of 0.05 μm-130 μm, an insulator disposed on the conductive core with thickness in a range of 0.09 μm-180 μm, and a conductive shield layer disposed on the insulator with thickness in a range of 0.009 μm-17 μm.

2. The manufacture of claim 1 wherein the outer diameter of the coaxial wire is in a range of 412 μm-550 μm, the outer diameter of the core is in a range of 103 μm-130 μm, the thickness of the insulator is in a range of 141 μm-180 μm, and the thickness the shield layer is in a range of 13 μm-17 μm.

3. The manufacture of claim 2 wherein the outer diameter of the coaxial wire is approximately 506 μm, the outer diameter of the core is approximately 127 μm, the thickness of the insulator is approximately 174 μm, and the thickness of the shield layer is approximately 15.9 μm.

4. The manufacture of claim 1 wherein the outer diameter of the coaxial wire is in a range of 260 μm-412 μm, the outer diameter of the core is in a range of 65 μm-103 μm, the thickness of the insulator is in a range of 89 μm-141 μm, and the thickness the shield layer is in a range of 8.2 μm-13 μm.

5. The manufacture of claim 4 wherein the outer diameter of the coaxial wire is approximately 318 μm, the outer diameter of the core is approximately 79.9 μm, the thickness of the insulator is approximately 109 μm, and the thickness of the shield layer is approximately 10 μm.

6. The manufacture of claim 1 wherein the outer diameter of the coaxial wire is in a range of 150 μm-260 μm, the outer diameter of the core is in a range of 38 μm-65 μm, the thickness of the insulator is in a range of 51 μm-89 μm, and the thickness the shield layer is in a range of 4.7 μm.

7. The manufacture of claim 6 wherein the outer diameter of the coaxial wire is approximately 200 μm, the outer diameter of the core is approximately 50.2 μm, the thickness of the insulator is approximately 68.7 μm, and the thickness of the shield layer is approximately 6.31 μm.

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. A manufacture including a coaxial wire with a 5-Ohm impedance and an outer diameter in a range of 0.1 μm-550 μm, the coaxial wire having a conductive core with an outer diameter in a range of 0.05 μm-304 μm, an insulator disposed on the conductive core with thickness in a range of 0.005 μm-24 μm, and a conductive shield layer disposed on the insulator with thickness in a range of 0.02 μm-99 μm.

21. The manufacture of claim 20 wherein the outer diameter of the coaxial wire is in a range of 365 μm-550 μm, the outer diameter of the core is in a range of 202 μm-304 μm, the thickness of the insulator is in a range of 16 μm-24 μm, and the thickness of the shield layer is in a range of 66 μm-99 μm.

22. The manufacture of claim 21 wherein the outer diameter of the coaxial wire is approximately 500 μm, the outer diameter of the core is approximately 276 μm, the thickness of the insulator is approximately 21.4 μm, and the thickness of the shield layer is approximately 90.3 μm.

23. The manufacture of claim 20 wherein the outer diameter of the coaxial wire is in a range of 166 μm-365 μm, the outer diameter of the core is in a range of 92 μm-202 μm, the thickness of the insulator is in a range of 7.1 μm-16 μm, and the thickness of the shield layer is in a range of 30 μm-66 μm.

24. The manufacture of claim 23 wherein the outer diameter of the coaxial wire is approximately 230 μm, the outer diameter of the core is approximately 127 μm, the thickness of the insulator is approximately 9.86 μm, and the thickness of the shield layer is approximately 41.5 μm.

25. The manufacture of claim 20 wherein the outer diameter of the coaxial wire is in a range of 87 μm-166 μm, the outer diameter of the core is in a range of 48 μm-92 μm, the thickness of the insulator is in a range of 3.7 μm-7.1 μm, and the thickness of the shield layer is in a range of 15.7 μm-30 μm.

26. The manufacture of claim 25 wherein the outer diameter of the coaxial wire is approximately 102 μm, the outer diameter of the core is approximately 56.4 μm, the thickness of the insulator is approximately 4.38 μm, and the thickness of the shield layer is approximately 18.4 μm.

27. The manufacture of claim 20 wherein the outer diameter of the coaxial wire is in a range of 61 μm-87 μm, the outer diameter of the core is in a range of 34 μm-48 μm, the thickness of the insulator is in a range of 2.6 μm-3.7 μm, and the thickness of the shield layer is in a range of 11.1 μm-15.7 μm.

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. The manufacture of claim 1 wherein the conductive core is formed from Cu or Cu/Ag alloy.

44. The manufacture of claim 1 wherein the insulator is formed from polyimide or Perfluoroalkoxy (PFA).

45. The manufacture of claim 1 wherein the shield layer is formed from Cu or Au.

46. (canceled)

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)

59. (canceled)

60. (canceled)

61. (canceled)

62. (canceled)

63. (canceled)

64. (canceled)

65. (canceled)

66. The manufacture of claim 20 wherein the conductive core is formed from Cu or Cu/Ag alloy.

67. The claim 20 wherein the insulator is formed from polyimide or Perfluoroalkoxy (PFA).

68. The manufacture of claim 20 wherein the shield layer is formed from Cu or Au.
